(19) United States
(12) Patent Application Publication
(10) Pub. No.: US 2026/0305336 A1
(43) Pub. Date: Oct. 1, 2026

(54) STRUCTURES AND PROCESSES FOR ATTACHING COLD PLATES TO MULTI CHIP MODULES

(71) Applicant: Adeia Semiconductor Bonding Technologies Inc., San Jose, CA (US)

(72) Inventors: Gaius Gillman Fountain, JR., Youngsville, NC (US); Pawel Mrozek, San Jose, CA (US); Kushal Rijal, Cary, NC (US); Belgacem Haba, Saratoga, CA (US); Cyprian Emeka Uzoh, San Jose, CA (US); Rajesh Katkar, Milpitas, CA (US)

(21) Appl. No.: 19/178,215

(22) Filed: Apr. 14, 2025

Related U.S. Application Data
(60) Provisional application No. 63/781,732, filed on Apr. 1, 2025.

(51) Int. Cl. H01L 23/433; H01L 23/00; H01L 23/31

(52) U.S. Cl. CPC H10W 40/237; H10W 40/233; H10W 40/40; H10W 40/43; H10W 40/47; H10W 42/121; H10W 90/155

(57) ABSTRACT

A device package comprising an integrated cooling assembly and method of forming the same. The device package comprises a multi-chip module (MCM) comprising chips attached to a substrate, and at least one silicon preform disposed adjacent to the MCM. A cold plate is attached to the chips and at least one silicon preform.

### CROSS REFERENCE TO RELATED APPLICATION

This application claims the benefit of U.S. Provisional Patent Application No. 63/781,732 filed Apr. 1, 2025, which is hereby incorporated by reference herein in its entirety.

### FIELD

The present disclosure relates to advanced packaging for microelectronic devices, and in particular, cooling systems for device packages and methods of manufacturing the same.

### BACKGROUND

Energy consumption poses a critical challenge for the future of large-scale computing as the world's computing energy requirements are rising at a rate that most would consider unsustainable. Some models predict that the information, communication and technology (ICT) ecosystem could exceed 20% of global electricity use by 2030, with direct electrical consumption by large-scale computing centers accounting for more than one-third of that energy usage. A significant portion of the energy used by such large-scale computing centers is devoted to cooling, since even small increases in operating temperatures can negatively impact the performance of microprocessors, memory devices, and other electronic components. While some of this energy is expended to operate the cooling systems that are directly cooling the chips (e.g., heat spreaders, heat pipes, etc.), energy consumption/costs for indirect cooling can also be quite staggering. Indirect cooling energy costs include, for example, cooling or air conditioning of data center buildings. Data center buildings can house thousands, to tens of thousands or more, of high performance chips in server racks, and each of those high performance chips is a heat source. An uncontrolled ambient temperature in a data center will adversely affect the performance of the individual chips, and the data center system performance as a whole.

Thermal dissipation in high-power density chips (semiconductor devices/die) is also a critical challenge as improvements in chip performance, e.g., through increased gate or transistor density due to advanced processing nodes, evolution of multi-core microprocessors, etc., have resulted in increased power density and a corresponding increase in thermal flux that contributes to elevated chip temperatures. Higher density of transistors also increases the length of metal wiring on the chips, which generates its own additional thermal flux due to Joule heating of these wires due to higher currents. Higher density of transistors also increases the length of submicron width metal wiring within the metallization of the chips, which generates its own additional thermal flux due to Joule heating of these wires due to higher resistances and the higher current densities. These elevated temperatures are undesirable as they can degrade the chip's operating performance, efficiency, reliability, and amount of remaining life. Cooling systems used to maintain the chip at a desired operating temperature typically remove heat using one or more heat dissipation devices, e.g., thermal spreaders, heat pipes, cold plates, liquid cooled heat pipe systems, thermal-electric coolers, heat sinks, etc. One or more thermal interface materials (TIMs), such as, for example, thermal paste, thermal adhesive, or thermal gap filler, may be used to facilitate heat transfer between the surfaces of a chip and heat dissipation device(s). A thermal interface material is any material that is inserted between two components to enhance the thermal coupling therebetween. Unfortunately, the combined thermal resistance of (i) the interfacial boundary regions between one or more TIMs and the chip and/or the heat dissipation device(s), and (ii) the thermal interface material itself can inhibit heat transfer from the chip to the heat dissipation devices, undesirably reducing the cooling efficiency of the cooling system.

Generally speaking, there are multiple components between the heat dissipating sources (i.e., active circuitry) in the chips and the heat dissipation devices, each of which contributes to the system thermal resistance cumulatively along the heat transfer paths and raises chip junction temperatures from the ambient. Such cooling systems can suffer from reduced cooling efficiency due to the design, manufacture of system components, and assembly of these components.

Accordingly, there exists a need in the art for improved energy-efficient cooling systems, by reducing system thermal resistance, methods of manufacturing the same, and the assembly of the various components.

### SUMMARY

Embodiments herein provide integrated cooling assemblies embedded in advanced device packages. Advantageously, the integrated cooling assemblies use a preformed frame around one or more multi-chip module (MCM) to support planarization and enhance flattening of the MCM for improved bonding in a cooling assembly. The preformed frame may comprise one or more silicon preforms (e.g., pieces or strips of silicon, dummy silicon). Advantageously, a silicon preform can be used to help protect components (e.g., chip resistors, capacitors, passive elements) on the module substrate during polishing, can help to support edges of a cold plate (e.g., silicon cold plate), and can allow more overhang of the cold plate bonded periphery to help ensure a more robust liquid seal to the cold plate.

A first general aspect includes an integrated cooling assembly comprising a substrate, a plurality of chips attached to the substrate, at least one silicon preform adjacent to the plurality of chips and attached to the substrate, and a cold plate attached to the plurality of chips and the at least one silicon preform.

In some embodiments, the integrated cooling assembly further comprises a molding material disposed between the plurality of chips and the at least one silicon preform. A surface of the molding material may be recessed from a surface of the plurality of chips and the at least one silicon preform.

In some embodiments, the integrated cooling assembly further comprises at least one capacitor disposed in a molding material between the substrate and the at least one silicon preform.

In some embodiments, the at least one silicon preform is a single silicon piece that surrounds the plurality of chips. In some embodiments, the at least one silicon preform comprises a plurality of silicon pieces that surround the plurality of chips.

In some embodiments, the integrated cooling assembly further comprises a dielectric layer on a backside of at least one chip of the plurality of chips and a dielectric layer on a backside of the at least one silicon preform, and a dielectric layer on a side of the cold plate facing the plurality of chips and the at least one silicon preform. The dielectric layer on the backside of the at least one chip and the dielectric layer on the backside of the at least one silicon preform may be directly bonded to the dielectric layer on the side of the cold plate facing the plurality of chips and the at least one silicon preform. The cold plate may comprise a first portion and a second portion that are directly bonded to each other.

In some embodiments, the integrated cooling assembly further comprises a metal stiffener attached to the substrate and surrounding the at least one silicon preform. The integrated cooling assembly may further comprise a molding material disposed between the plurality of chips and the at least one silicon preform. A surface of the molding material may be recessed from a surface of the plurality of chips, the at least one silicon preform, and the metal stiffener.

In some embodiments, the metal stiffener is a first metal stiffener. The integrated cooling assembly may further comprise a second metal stiffener attached to the first metal stiffener via adhesive or metallic bonding or dielectric or hybrid bonding, and a manifold attached to the cold plate and adjacent to the second metal stiffener.

A second general aspect includes a method. The method includes attaching a silicon preform to a substrate comprising a plurality of chips disposed in a molding material. The silicon preform surrounds the plurality of chips. The method further includes backgrinding the chips, the silicon preform, and the molding material to form a planar surface. The method further includes polishing the chips and the silicon preform (e.g., silicon surfaces) with a hard pad, recessing the molding material below a surface of the chips and the at least one silicon preform, polishing the chips and the silicon preform (e.g., silicon surfaces) with a soft or softer pad, and bonding a cold plate to the plurality of chips and the silicon preform.

In some embodiments, the method further comprises forming a dielectric layer on a backside of at least one chip of the plurality of chips, forming a dielectric layer on a backside of the silicon preform, forming a dielectric layer on a side of the cold plate, and bonding the dielectric layer on the backside of the at least one chip and the dielectric layer on the backside of the silicon preform to the dielectric layer on the side of the cold plate.

In some embodiments, the method further comprises forming the cold plate by directly bonding a first portion of the cold plate to a second portion of the cold plate.

In some embodiments, the method further comprises, prior to backgrinding the chips, the silicon preform, and the molding material to form the planar surface, recessing a metal stiffener surrounding the silicon preform to be below the height of the chips.

In some embodiments, metal stiffener is a first metal stiffener. The method may further comprise attaching a second metal stiffener to the first metal stiffener via adhesive or metallic bonding or dielectric or hybrid bonding, and attaching a manifold to the cold plate adjacent to the second metal stiffener.

In some embodiments, the method further includes, prior to backgrinding the chips, the silicon preform, and the molding material to form the planar surface, attaching a plate (e.g., protective plate, metal plate, silicon plate, or carrier wafer) to a bottom of the substrate, and subsequent to bonding the cold plate to the plurality of chips and the silicon preform, removing the plate.

A third general aspect includes a method. The method comprises attaching at least one silicon preform to a substrate comprising groups of plurality of chips disposed in a molding material. The at least one silicon preform is disposed in an area adjacent to at least one group of the plurality of chips. The method further comprises backgrinding the groups of the plurality of chips, the at least one silicon preform, and the molding material to form a planar surface. The method further comprises polishing the chips and the at least one silicon preform (e.g., silicon surfaces) with a hard pad, recessing the molding material below a surface of the chips and the at least one silicon preform, polishing the chips and the at least one silicon preform (e.g., silicon surfaces) with a soft or softer pad, and bonding at least one cold plate to the at least one silicon preform and respective group of the plurality of chips.

In some embodiments, the method comprises attaching at least one silicon preform to a substrate comprising groups of plurality of chips disposed in an inorganic material. The at least one silicon preform is disposed in an area adjacent to at least one group of the plurality of chips. The method further comprises back grinding the groups of the plurality of chips, the at least one silicon preform, and the inorganic material to form a planar surface. In this method, bonding the chip or plurality of chips, one or more inorganic material is coated over the bonded chip or chips before the planarization process or processes. Also multiple inorganic coating and planarization steps may be used to form the planar and smooth bonding surface of the backside of the chips and the silicon preform.

In some embodiments, the at least one silicon preform is a plurality of silicon preforms, and the at least one cold plate is a plurality of cold plates. In some embodiments, the at least one silicon preform is a single silicon preform. In some embodiments, the at least one silicon preform is a rectangular shaped strip that is adjacent to more than one group of the plurality of chips.

### BRIEF DESCRIPTION OF THE DRAWINGS

The above and other objects and advantages of the disclosure will be apparent upon consideration of the following detailed description, taken in conjunction with the accompanying drawings, in which:

FIG. 1 illustrates a device package with an external heat sink;

FIG. 2A is a schematic plan view of an example of a system panel, in accordance with embodiments of the present disclosure;

FIG. 2B is a schematic partial side view of a device package mounted on a PCB, in accordance with embodiments of the present disclosure;

FIG. 2C is a schematic exploded isometric view of the device package in FIG. 2B;

FIG. 2D shows schematic views of a cold plate, in accordance with embodiments of the present disclosure;

FIG. 2E shows schematic views of an MCM assembly, in accordance with embodiments of the present disclosure;

FIG. 3 is a schematic sectional view of an example device package, in accordance with embodiments of the present disclosure, that may be used with the system panel;

FIG. 4 is a schematic sectional view in the Y-Z plane of the integrated cooling assembly of FIG. 3, in accordance with embodiments of the present disclosure;

FIG. 5 shows schematic views of an MCM assembly, in accordance with embodiments of the present disclosure, that may be used with the system panel;

FIG. 6 is a schematic sectional view of another example device package, in accordance with embodiments of the present disclosure, that may be used with the system panel;

FIG. 7 shows a method that can be used to manufacture the device package described herein;

FIG. 8 shows an example method of attaching a silicon preform to an MCM, in accordance with embodiments of the present disclosure;

FIGS. 9A-9D shows a top view of a silicon preform design to fit around a panel of MCMs, in accordance with embodiments of the present disclosure; and

FIGS. 10A-10C and FIGS. 11A-11F show methods of forming a cooling assembly with an MCM using a silicon preform, in accordance with embodiments of the present disclosure.

The figures herein depict various embodiments of the present disclosure for purposes of illustration only. It will be appreciated that additional or alternative structures, assemblies, systems, and methods may be implemented within the principles set out by the present disclosure.

### DETAILED DESCRIPTION

As used herein, the term “substrate” means and includes any workpiece, wafer, or article that provides a base material or supporting surface from which or upon which components, elements, devices, assemblies, modules, systems, or features of the heat-generating devices, packaging components, and cooling assembly components described herein may be formed or mounted. The term “substrate” also includes semiconductor substrates that provide a supporting material upon which elements of a semiconductor device are fabricated or attached, and any material layers, features, and/or electronic devices formed thereon, therein, or therethrough. Examples of substrate material that may be used in applications that generate high thermal density include, but are not limited to, Si, GaN, SiC, InP, GaP, InGaN, AlGaInP, AlGaAs, etc.

As used herein, the term “chip” may refer to a semiconductor device, device, processor, Graphics Processing Unit (GPU) core, X-Processing Unit (XPU) (e.g., CPUs, GPUs, any suitable processing unit, etc.), High-Bandwidth Memory (HBM), stacked Dynamic Random-Access Memory (DRAM), etc.

As described below, the semiconductor substrates herein generally have a “device side,” e.g., the side on which semiconductor device elements are fabricated, such as transistors, resistors, and capacitors, and a “backside” that is opposite the device side. The term “active side” should be understood to include a surface of the device side of the substrate and may include the device side surface of the semiconductor substrate and/or a surface of any material layer, device element, feature, or metallization features formed thereon or extending outwardly therefrom, and/or any openings formed therein. Thus, it should be understood that the material(s) that forms the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active sides” and “non-active sides” are also used to describe surfaces of material layers or features formed on, in, or through the semiconductor substrate, whether or not the material layers or features are ultimately present in the fabricated or assembled device. For example, in some instances, the term “active side” is used to indicate a surface of a substrate that will in the future, but does not yet, include semiconductor device elements.

Spatially relative terms are used herein to describe the relationships between elements, such as the relationships between substrates, heat-generating devices, cooling assembly components, device packaging components, and other features described below. Unless the relationship is otherwise defined, terms such as “above,” “over,” “upper,” “upwardly,” “outwardly,” “on,” “below,” “under,” “beneath,” “lower,” “top,” “bottom” and the like are generally made with reference to the X, Y, and Z directions set forth by X, Y and Z axes in the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” and the like, either alone or in combination with a spatially relevant term, include both relationships with intervening elements and direct relationships where there are no intervening elements. Furthermore, the term “horizontal” is generally made with reference to the X-axis direction and the Y-axis direction set forth in the drawings. The term “vertical” is generally made with reference to the Z-axis direction set forth in the drawings.

Various embodiments disclosed herein include bonded structures in which two or more elements are directly bonded to one another without an intervening adhesive (referred to herein as “direct bonding,” or “directly bonded”). The resultant bonds formed by this technique may be described as “direct bonds”. In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. As discussed in more detail below, the process of direct bonding (e.g., direct dielectric bonding) provides a reduction of thermal resistance between a semiconductor device and a cold plate. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, silicon carbide, diamond, diamond like carbon (DLC), sapphire, glass, glass-ceramic, ceramics etc. Direct bonding can also include bonding of multiple materials on one element to multiple materials on the other element (e.g., hybrid bonding). As used herein, the term “hybrid bonding” refers to a species of direct bonding having both i) at least one (first) nonconductive feature directly bonded to another (second) nonconductive feature, and ii) at least one (first) conductive feature directly bonded to another (second) conductive feature, without any intervening adhesive or solder. The resultant bonds formed by this technique may be described as “hybrid bonds” and/or “direct hybrid bonds”. In some hybrid bonding embodiments, there are many first conductive features, each directly bonded to a second conductive feature, without any intervening adhesive or solder. In some embodiments, nonconductive features on the first element are directly bonded to nonconductive features of the second element at room temperature without any intervening adhesive, which is followed by direct bonding of conductive features of the first element to conductive features of the second element via annealing at slightly higher temperatures (e.g., >100° C., >200° C., >250° C., >300° C., etc.), wherein the annealing causes the conductive features to expand faster than the non-conductive features and to bond or mechanically and electrically couple together.

Unless otherwise noted, the terms “cooling assembly” and “integrated cooling assembly” generally refer to a semiconductor device and a cold plate attached to the semiconductor device. In some embodiments, the semiconductor device may be replaced by a plurality of semiconductor devices. The plurality of semiconductor devices may be disposed in or surrounded by a molding material on a substrate or package substrate, and may be referred to as an MCM. One or more silicon preforms may be attached to the MCM using molding material to form an MCM assembly. A cold plate may be attached to the MCM assembly. Typically, the cold plate is formed with recessed surfaces that define one or more fluid cavities (e.g., coolant chamber volume(s) or coolant channel(s)) between the cold plate and the semiconductor device. In embodiments where the cold plate is formed with plural fluid cavities, each fluid cavity may be defined by cavity dividers and/or sidewalls of the cold plate. For example, cavity dividers may be spaced apart from each other and extend laterally between opposing cold plate sidewalls (e.g., in one direction between a first pair of opposing cold plate sidewalls, or in two directions between orthogonal pairs of opposing cold plate sidewalls). The cavity dividers and the cold plate sidewalls may collectively define adjacent fluid cavities therebetween. While it is preferred that the cold plate is formed of a material whose coefficient of linear thermal expansion (CTE) is the same as or similar to the bulk material of the semiconductor device, in some embodiments the cold plate may comprise one or more materials such as: conductive polymer, polymer reinforced with conductive materials or particulates, polymer, copper, aluminum, silicon, glass, or ceramic, for example.

The cold plate may be attached to the semiconductor device by use of an adhesive layer or by direct bonding or hybrid bonding. Direct bonding may include direct dielectric bonding techniques as described herein, and may give rise to direct dielectric bonds. Hybrid bonding may include hybrid bonding techniques as described herein, and may give rise to direct hybrid bonds. For example, the cold plate may include material layers and/or metal features that facilitate direct bonding or hybrid bonding with the semiconductor device. In some embodiments, the backside of the semiconductor device is beneficially directly exposed to coolant fluids flowing through the integrated cooling assembly, thus providing for direct heat transfer therebetween. It will be understood that “coolant fluid” may alternatively be referred to as “cooling fluid”. Unless otherwise noted, the integrated cooling assemblies described herein may be used with any desired fluid, e.g., liquid, gas, and/or vapor-phase coolants, such as water, glycol, etc. In some embodiments, the coolant fluid(s) may contain additives to enhance the conductivity of the coolant fluid(s) within the integrated cooling assemblies. The additives may comprise, for example, nanoparticles of various types, such as carbon nanotubes, graphene, and/or metal oxides. The concentration of these nanoparticles within the coolant fluid may be less than 1%, less than 0.2%, or less than 0.05%. The coolant fluids may also contain a small amount of glycol or glycols (e.g., propylene glycol, ethylene glycol, etc.) to reduce frictional shear stress and drag coefficient in the coolant fluid(s) within the integrated cooling assembly. In some embodiments the coolant fluid may contain entirely glycol or glycols.

Exemplary fluids available for use in the various thermal solution embodiments include: water (either purified or deionized), a glycol (e.g., ethylene glycol, propylene glycol), glycols mixed with water (e.g., ethylene glycol mixed with water (EGW) or propylene glycol mixed with water (PGW)), dielectric fluids (e.g. fluorocarbons, polyalphaolefin (PAO), isoparaffins, synthetic esters, or very high viscosity index (VHVI) oils), or mineral oils. Additionally, depending upon design and operating conditions, these fluids may be used in single-phase liquid, single-phase vapor, two-phase liquid/vapor or two-phase solid/liquid. By adjusting the fluid selection and the relative fluid concentrations in the fluid mixtures, it is possible to alter the thermohydraulic and heat transfer properties by altering the temperatures where phase change occurs, enabling meeting design temperature and pressure conditions for the component being cooled or warmed and the thermal solution being deployed. Additionally, different combinations of the fluid phases may be employed in various hybrid configurations to meet the particular cooling or warming needs of a respective implementation and still be within the scope of the contemplated embodiments.

Additionally, in some embodiments part or all the cooling is provided by gases. Exemplary gases include atmospheric air and/or one or more inert gases such as nitrogen. Atmospheric air may be taken to mean the mixture of different gases in Earth's atmosphere made up of about 78% nitrogen and 21% oxygen.

Depending on the design needs of a thermal solution system using the disclosed embodiments, engineered dielectric coolant fluids may be used. As used herein, a dielectric coolant fluid is a fluid that is thermally conductive but not electrically conductive. Some examples of dielectric fluids used for cooling semiconductors include: 3M™ Fluorinert™ Liquid FC-40-A non-flammable, dielectric fluid that can be used in direct contact with live electronics; 3M™ Novec™ Engineered Fluids-A non-flammable, dielectric fluid that can be used in direct contact with live electronics; Galden® PFPE (perfluoropolyether) products used as heat transfer fluids; EnSolv Fluoro HTF-A solvent with a high boiling point and low pour point that can be used for semiconductor wafer cooling. It is understood that in the selection of the coolant fluid, system design aspects such as operating temperatures and pressures, fluid flow rates, fluid viscosity, and other properties will require evaluation when selecting the appropriate coolant fluid. In some embodiments, the cooling fluid may comprise of liquid nitrogen, liquid carbon dioxide or non-flammable liquefied gas.

In some embodiments, the coolant fluids may contain microparticles and/or nano-particle additives to enhance the conductivity of the coolant fluid within the integrated cooling assemblies. Nanofluids are engineered fluids prepared by suspending the nano-sized (1-100 nm) particles of metals/non-metals and their oxide(s) with a base/conventional fluid. The suspension of high thermal conductivity metals/non-metals and their oxides nano-particles enhances the thermal conductivity and heat transfer ability, etc. of the base fluid. The additives to the underlying coolant fluid may comprise for example, nano-particles of carbon nanotube, nano-particles of graphene, or nano-particles of metal oxides. When the coolant fluid contains microparticles, the microparticles are typically 10 microns or less in diameter. In some embodiments, silicon oxide microparticles may be used.

The volume concentration of these micro or nano-particles within the coolant fluid may be less than 1%, less than 0.2%, or less than 0.05%. Depending upon the liquid and micro/nano-particle type chosen for the coolant fluid, higher volume concentrations of 10% or less, 5% or less, or 2% or less may be used. The coolant fluids may also contain small amounts of glycol or glycols (e.g. propylene glycol, ethylene glycol etc.) to reduce frictional shear stress and drag coefficient in the coolant fluid within the integrated cooling assembly. The availability of different base fluids (e.g., water, ethylene glycol, mineral or other stable oils, etc.) and different nanomaterials provide a variety of nanomaterial options for nanofluid solutions to be used in the various embodiments. These nanomaterial option groups such as aforementioned metals (e.g., Cu, Ag, Fe, Au, etc.), metal oxides (e.g., TiO₂, Al₂O₃, CuO, etc.), carbons (e.g. CNTS, graphene, diamond, graphite . . . , etc.), or a mixture of different types of nanomaterials. Metal nano-particles (Cu, Ag, Au . . . ), metal oxide nano-particles (Al₂O₃, TiO₂, CuO), and carbon-based nano-particles are commonly employed elements. Silicon oxide nano-particles may also be used. Using coolant fluids with micro and/or nano-particles when practicing the various embodiments disclosed herein can result in increased heat removal efficiencies and effectiveness.

The fluid control design aspects of specific embodiments may require the nanofluids to be magnetic to facilitate either movement or cessation of movement of the fluids within the semiconductor structures. Magnetic nanofluids (MNFs) are suspensions of a non-magnetic base fluid and magnetic nano-particles. Magnetic nano-particles may be coated with surfactant layers such as oleic acid to reduce particle agglomeration and/or settling. Magnetic nano-particles used in MNFs are usually made of metal materials (ferromagnetic materials) such as iron, nickel, cobalt, as well as their oxides such as spinel-type ferrites, magnetite (Fe₃O₄), and so forth. The magnetic nano-particles used in MNFs typically range in size from about 1 to 100 nanometers (nm).

This disclosure describes embodiments involving the architecture of system and component elements that can be employed to provide for the cooling of semiconductor components, packaging, and boards. However, those skilled in the art will appreciate the disclosed components and arrangements can be deployed and used in scenarios where component heat up or thermal warm up is desired for a component that is currently outside the low end of the desired operational range. Components that are outside the low end of their operational range can, if started in a cold environment, experience thermal warping or cracking up to and including thermal overexpansion and contact separation that may impair the successful operation of the system. Therefore, in these scenarios, the architectures and embodiments disclosed herein can be used where the indirect thermal solutions supporting them are repurposed or operated in a hybrid configuration to provide warming fluids or heat transfer media to accomplish the warm-up or heat-up scenario. These scenarios are controlled by systems not shown here to bring temperatures up at a speed or timing that enables the materials to avoid the excessive thermal expansion or unequal thermal expansion that may occur among the materials of the semiconductor or packaging being serviced by the thermal solution. Once the component or packaging is brought up into the normal operating range, it can be safely started and brought to a useful operational state.

Considering the warm-up or heat-up embodiments introduced above, the balance of this disclosure and terms used should be viewed in a light that also considers the design option for such warm-up or heat-up. Thus, where terms such as cooling channel, cooling chamber volume, and cooling port are used, for example, such terms could also be considered as a thermal control channel, a thermal control volume, or a thermal control port, respectively. A person of skill would understand that heat flux or heat transfer would go in a different direction, but the design concepts are similar and can be successfully employed in the various embodiments.

In some embodiments, a cooling channel is a liquid cooling channel, and a liquid may flow through the liquid cooling channel. In some embodiments, the liquid may comprise a water and/or glycol (e.g., propylene glycol, ethylene glycol, and mixtures thereof).

As described below, coolant fluid flowing through a cold plate may be used to control the temperature of semiconductor devices. The fluid flowing across the surface of the semiconductor device absorbs heat and conducts heat away from the semiconductor device.

Multi-chip modules (MCMs) may include multiple chips, integrated circuits (ICs), semiconductor dies, or other components that are assembled onto a substrate. The chips (e.g., ICs, semiconductor dies, or other components) may be any suitable semiconductor device (e.g., processor, core processor, HBM, stacked DRAM, etc.). Multiple chips may be assembled into a modular form (e.g., MCM). MCMs or MCM chip assemblies may have a curvature of 80-100 microns over a distance of about 50 mm, making it difficult for bonding cold plate or sealing a liquid manifold to the cold plate. It may be difficult to planarize and smooth mounted chips without creating significant or excessive curvature of the chips. MCMs may have solder balls (e.g., solder bumps, conductive bumps, etc.) on the bottom and components (e.g., capacitor chips, chip capacitors, chip resistors, capacitors, resistors, passive elements, etc.) on the top, which may need protection during planarization and smoothing. Having solder balls at the bottom of the MCM may also prevent the MCM from being held with any sort of vacuum chuck, such as those used for smoothing and polishing process. Advantageously, one or more silicon preforms can be used to form an MCM assembly and help prevent significant or excessive curvature of chips and protect components (e.g., capacitor chips, chip capacitors, chip resistors, capacitors, resistors, passive elements, etc.) on the module substrate during smoothing and polishing. The one or more silicon preform can be attached using mold compound or other adhesive, and can help to support edges of the cold plate (e.g., silicon cold plate) and can allow more overhang of the cold plate bonded periphery to help ensure a more robust liquid seal to the cold plate. A plate (e.g., protective plate, metal plate, silicon plate, carrier wafer, etc.) may be temporarily affixed to the bottom of the module using wax or any suitable removable material. The plate and wax can protect solder balls (e.g., solder bumps, conductive bumps, etc.) and enable the MCM to be held from the backside with vacuum chucks such as those that are a part of a chemical mechanical polishing (CMP) tool wafer or substrate carrier. In some embodiments, a CMP carrier with membrane pressure/vacuum capability (e.g., an MCM carrier) may be used.

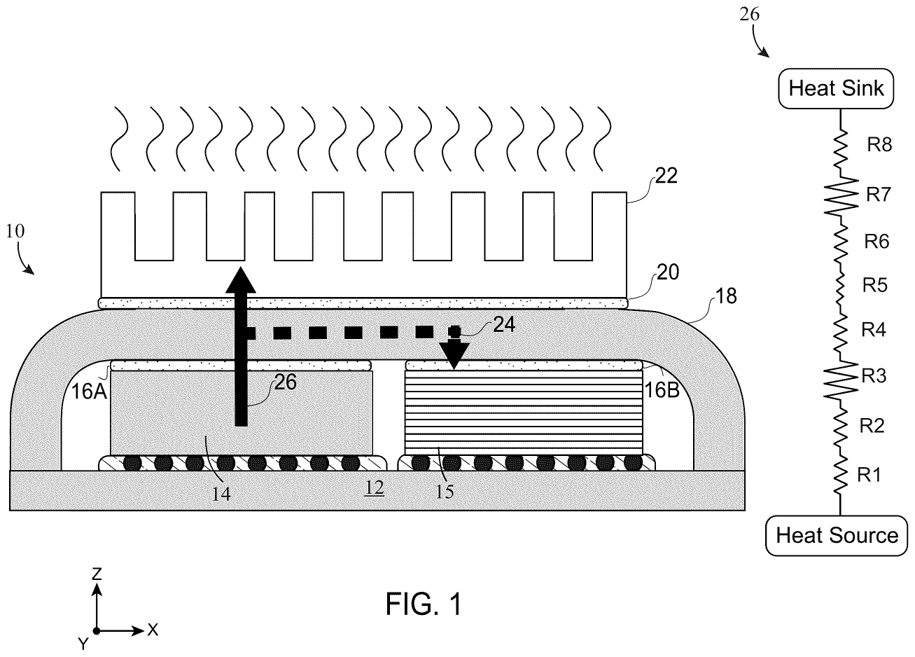

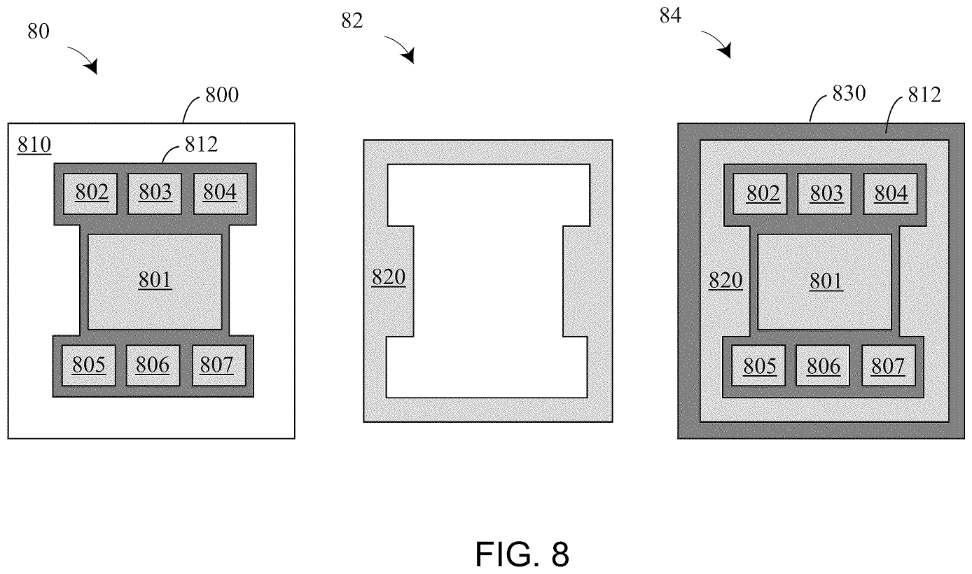

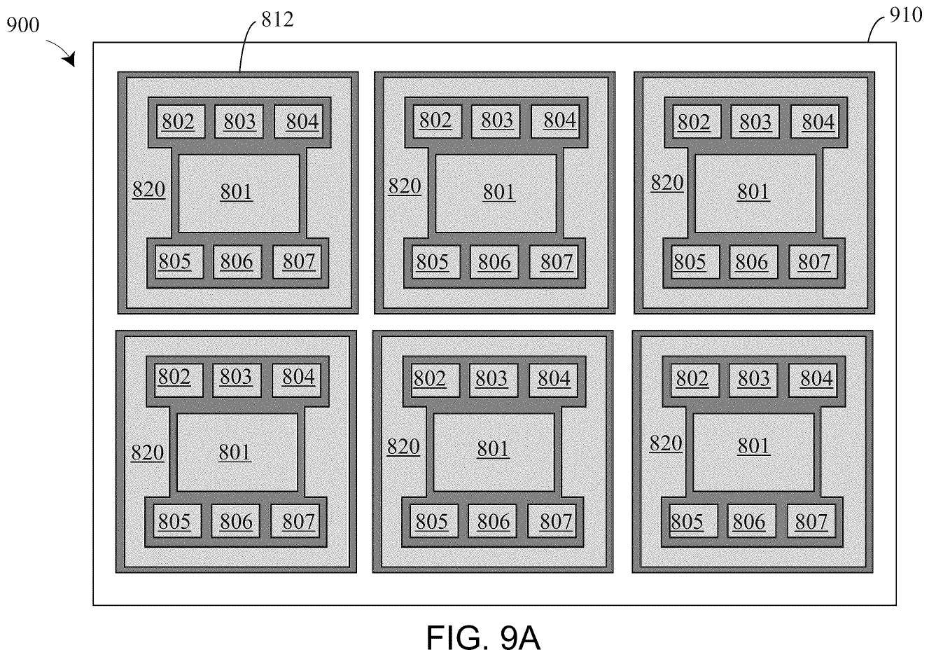

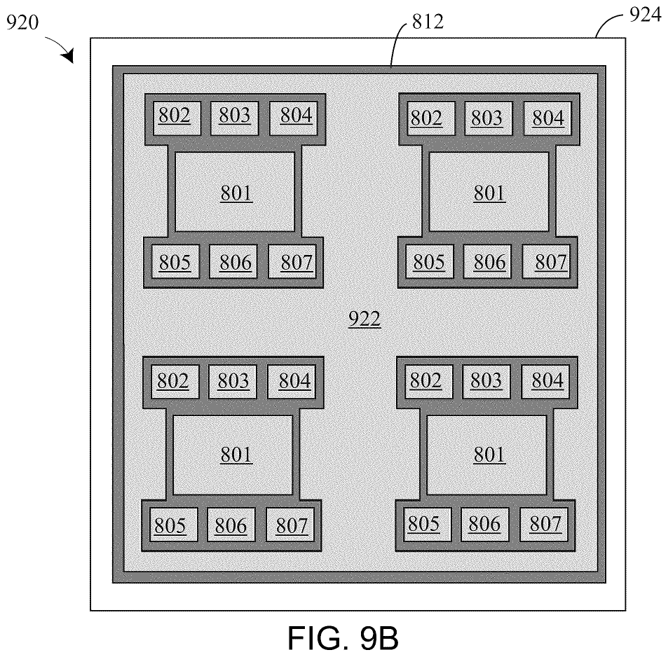

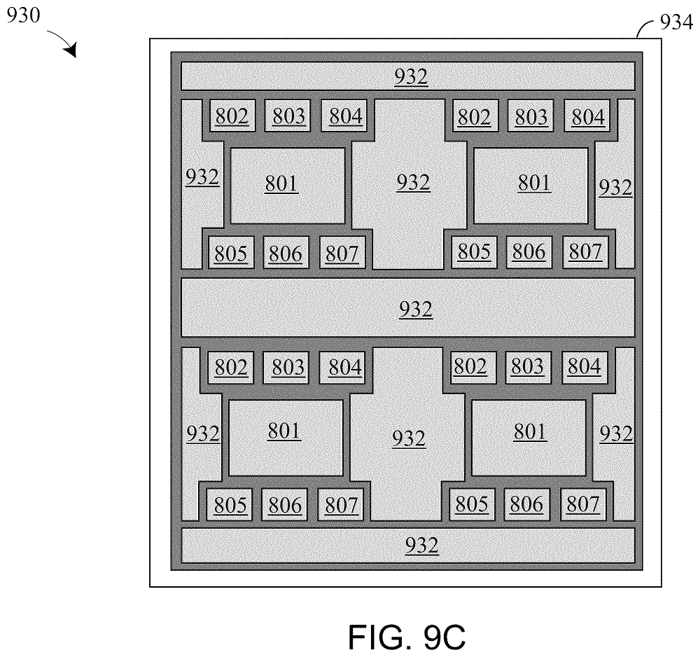

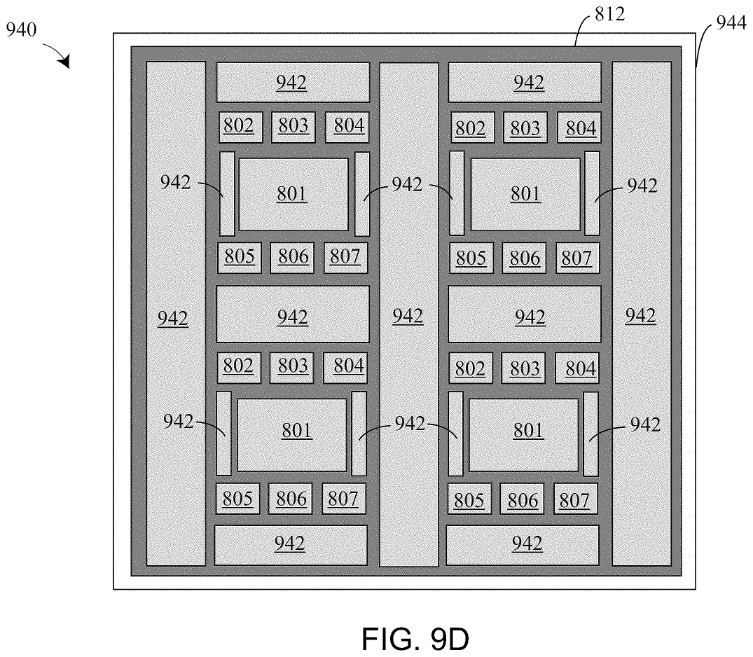

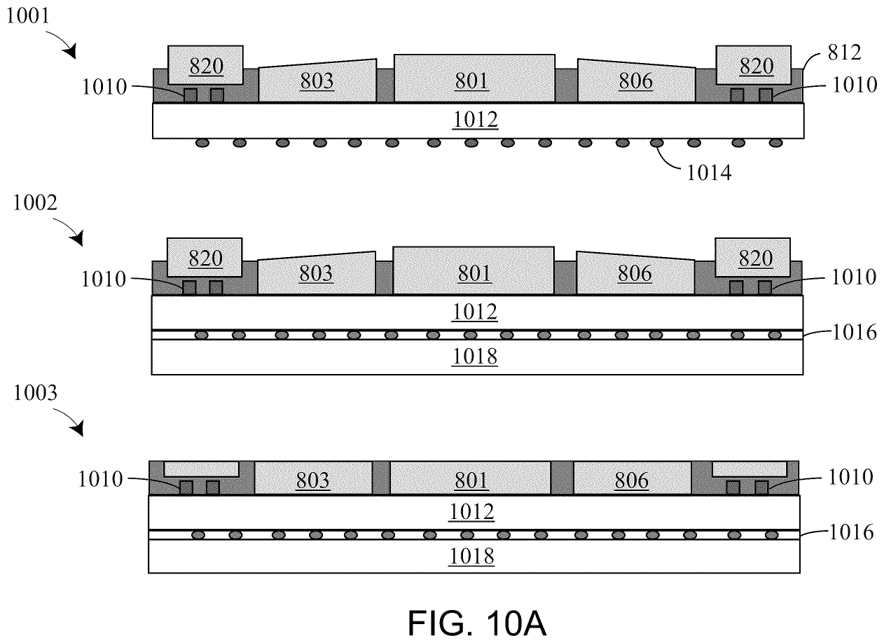

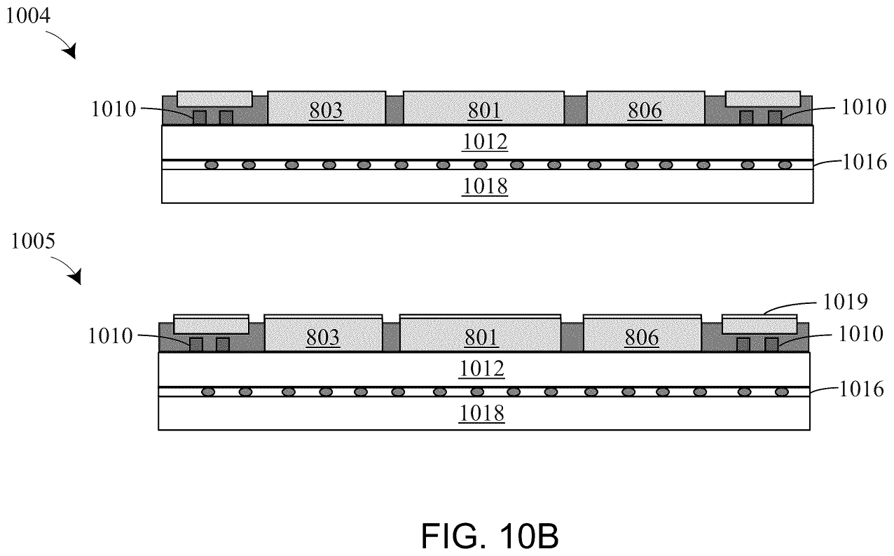

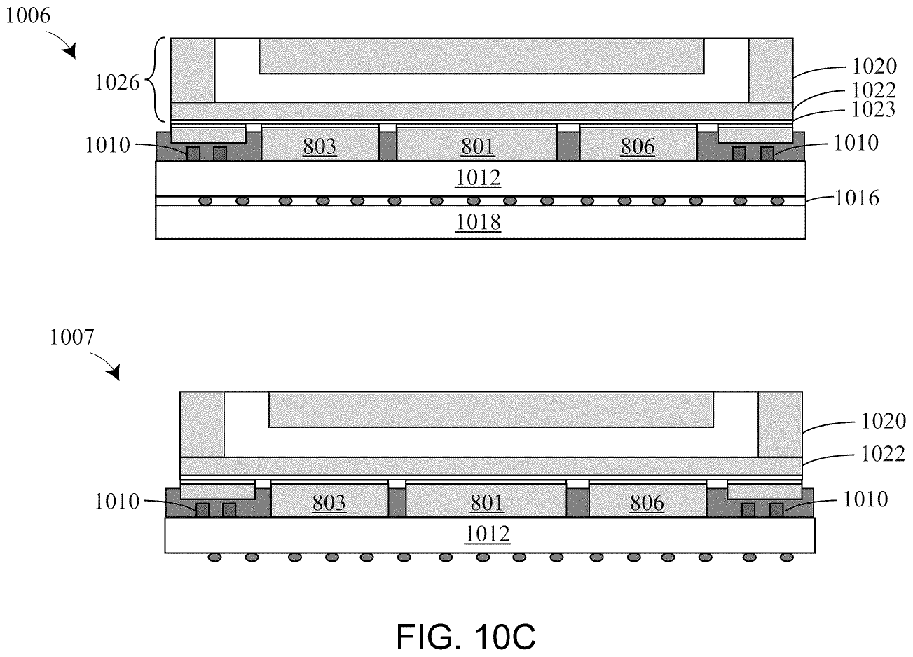

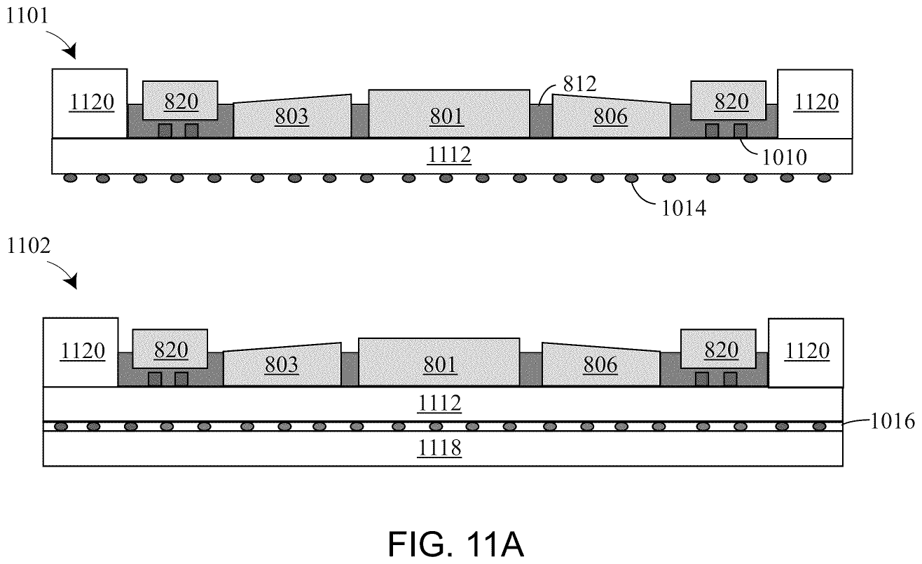

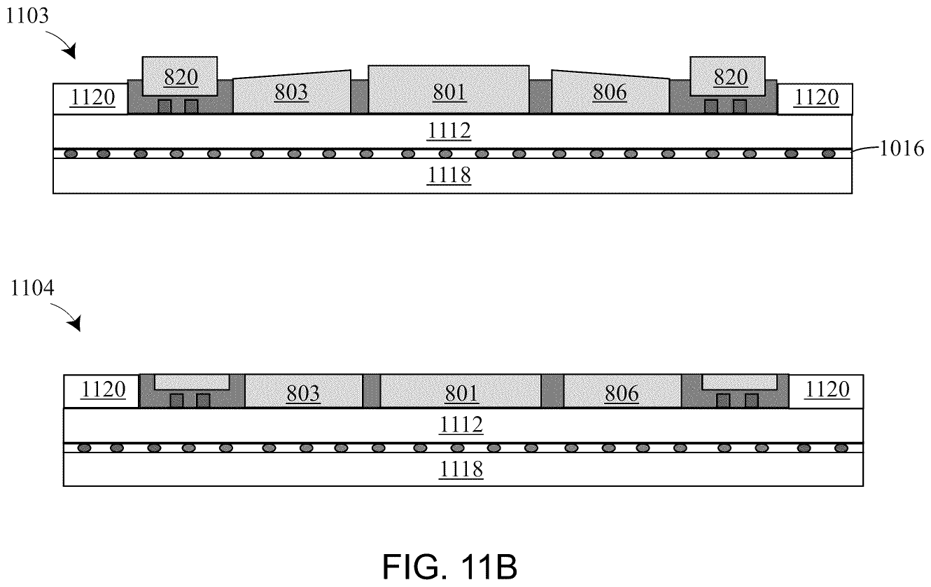

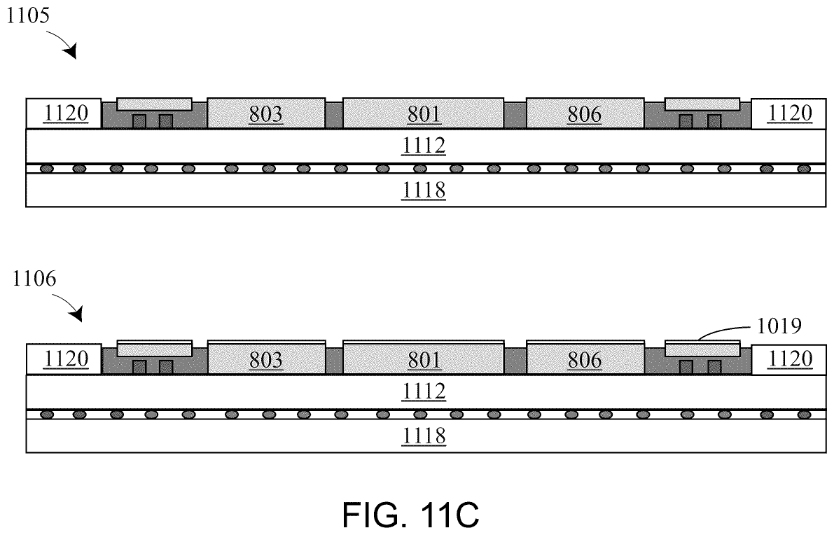

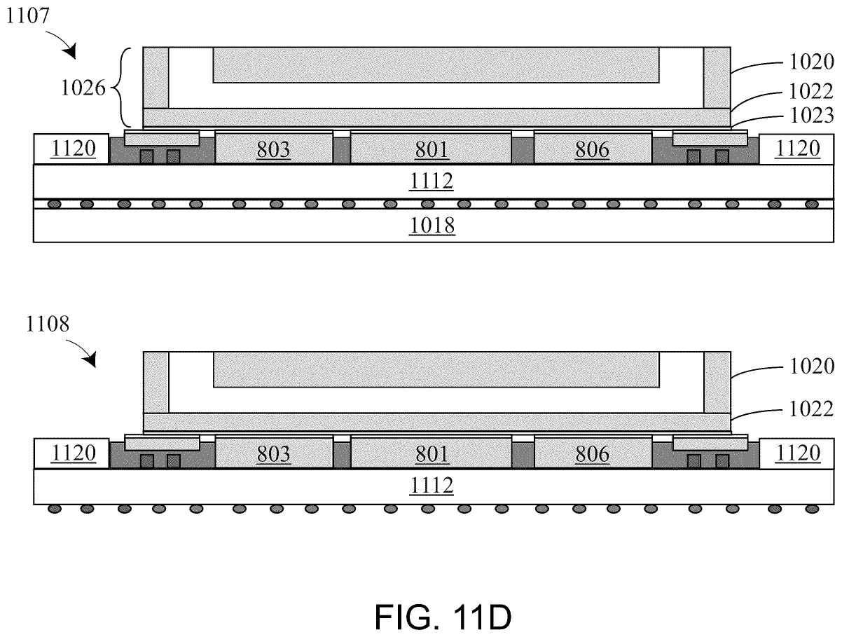

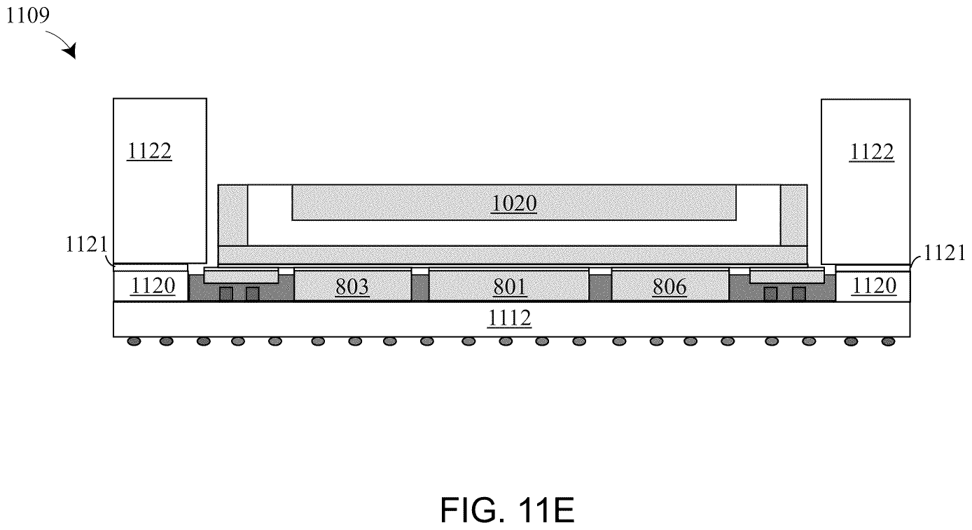

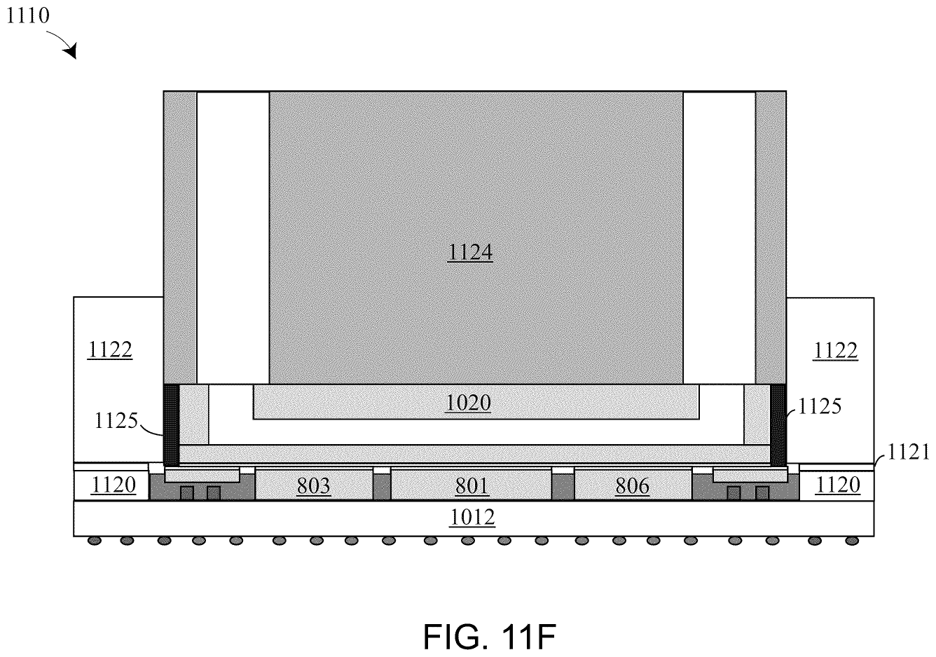

FIGS. 1-7 relate to various aspects of a cooling assembly, which may be applied towards cooling a configuration with multiple chips or an MCM. FIG. 8 schematically illustrates a method of attaching a silicon preform to an MCM to form an MCM assembly. FIGS. 9A-9D show various silicon preform designs comprising one or more silicon preforms for a panel of MCMs, in accordance with embodiments of the present disclosure. FIGS. 10A-10C and FIGS. 11A-11E show methods of forming a cooling assembly with an MCM using a silicon preform, in accordance with embodiments of the present disclosure. Although only one group of chips (e.g., an MCM) is shown in FIGS. 10A-10C and 11A-11F, the method may be applied to a panel of MCMs (e.g., a plurality of groups of chips such as those shown in FIG. 9A-9D, etc.).

FIG. 1 is a schematic side view of a device package 10 and a heat sink 22 attached to the device package 10. The device package 10 typically includes a package substrate 12, a first device 14, a device stack 15, a heat spreader 18, and first TIM layers 16A, 16B thermally coupling the first device 14 and the device stack 15 to the heat spreader 18. The device package 10 is thermally coupled to the heat sink 22 through a second TIM layer 20. The TIM layers 16A, 16B, 20 facilitate thermal contact between components in the device package 10 and between the device package 10 and the heat sink 22.

As heat flux density increases with increasing power density in advanced semiconductor devices, the cumulative thermal resistance of the system illustrated in FIG. 1 is increasingly problematic as heat cannot be dissipated quickly enough to allow semiconductor devices to run at optimal power. Consequently, the energy efficiency of semiconductor devices is reduced. Furthermore, heat is transferred between semiconductor devices within the device package 10, as shown with heat transfer path 24 (illustrated as a dashed line), where heat may be undesirably transferred from the first device 14 having a high heat flux, such as a central processing unit (CPU) or a graphical processing unit (GPU), to the device stack 15 having low heat flux, such as memory, through the heat spreader 18.

For example, as shown in FIG. 1, each device package component and the respective interfacial boundaries therebetween have a corresponding thermal resistance that forms heat transfer path 26 (illustrated by arrow 26 in FIG. 1). The right-hand side of FIG. 1 illustrates the heat transfer path 26 as a series of thermal resistances R1-R8 between a heat source and a heat sink. Here, R1 is the thermal resistance of the bulk semiconductor material of the first device 14. R3 and R7 are the thermal resistances of the first TIM layers 16A, 16B and the second TIM layer 20, respectively. R5 is the thermal resistance of the heat spreader 18. R2, R4, R6, and R8 represent the thermal resistance at the interfacial region of the components (e.g., contact resistances). In a typical cooling system, R3 and R7 may account for 80% or more of the cumulative thermal resistance of the heat transfer path 26, and R5 may account for 5% or more. R1 of the first device 14 and R2, R4, R6, and R8 of the interfaces account for the remaining cumulative thermal resistance. Accordingly, embodiments described herein provide for integrated cooling assemblies embedded within a device package. The embedded cooling assemblies shorten the thermal resistance path between a semiconductor device and a heat sink and reduce thermal communication between semiconductor devices disposed in the same device package, such as described in relation to the figures below.

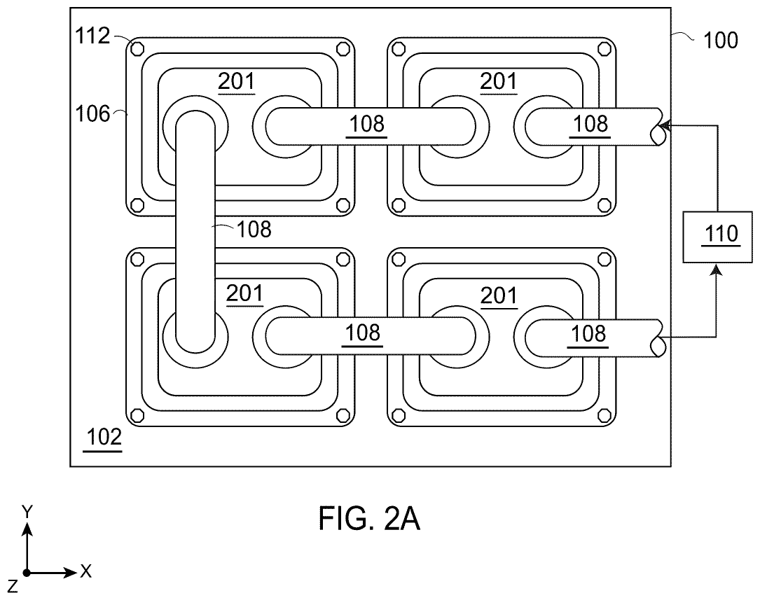

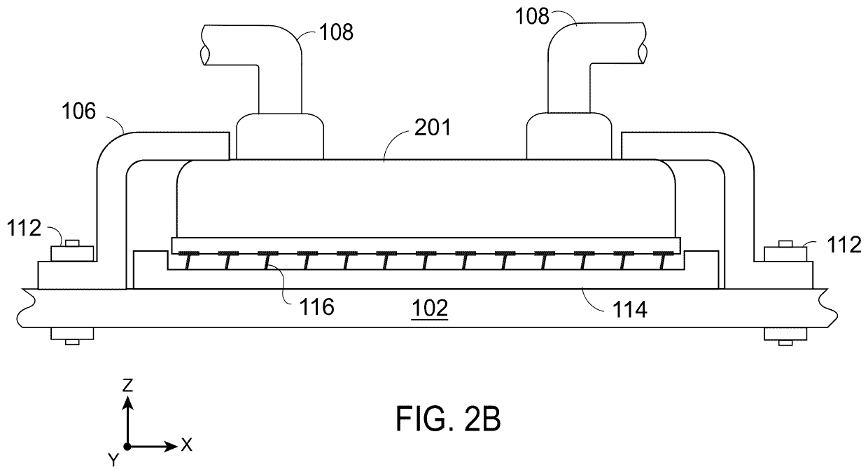

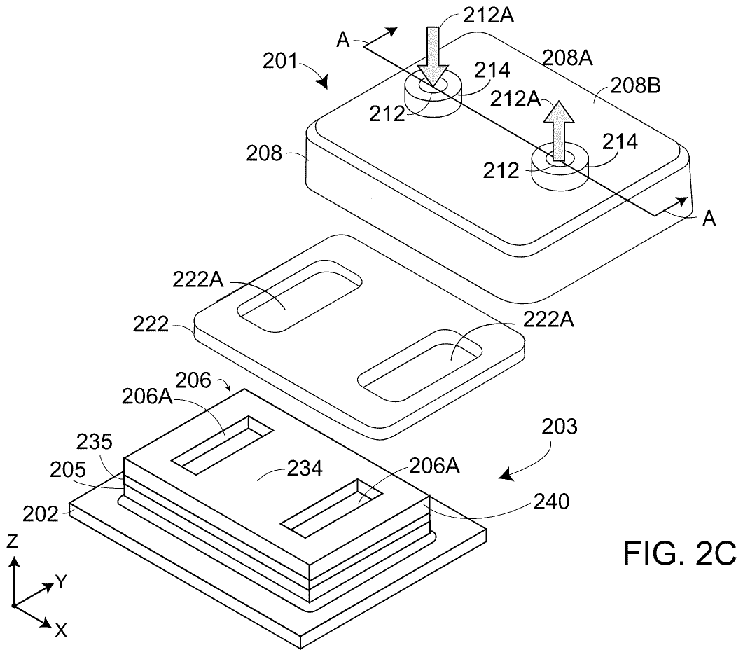

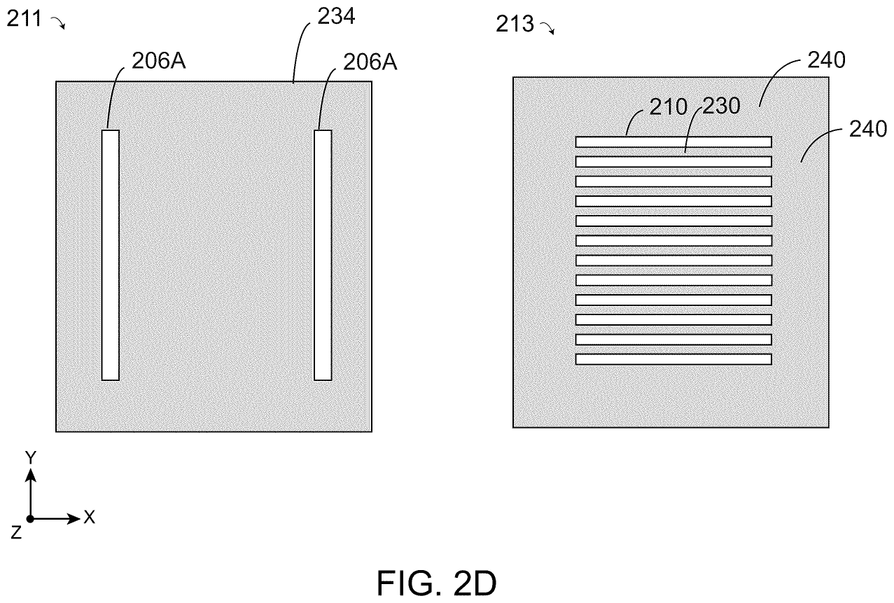

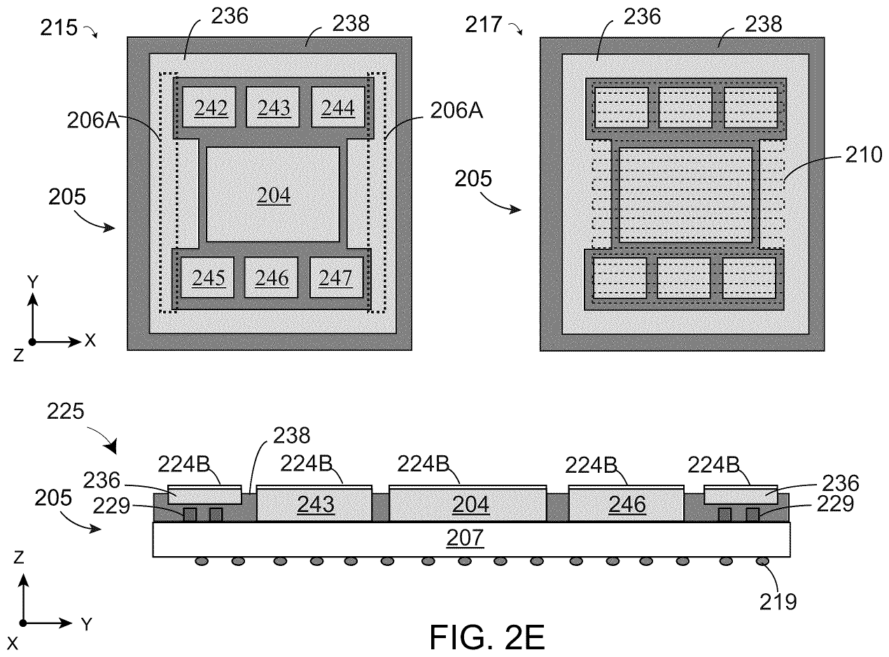

FIG. 2A is a schematic plan view of an example of a system panel 100, in accordance with embodiments of the present disclosure. Generally, the system panel 100 includes a printed circuit board (PCB) 102, a plurality of device packages 201 mounted to the PCB 102, and a plurality of coolant lines 108 fluidly coupling each of the device packages 201 to a coolant source 110. It is contemplated that coolant fluid may be delivered to each of the device packages 201 in any desired fluid phase, e.g., liquid, vapor, gas, or combinations thereof, and may flow out from each device package 201 in the same phase or a different phase. In some embodiments, the coolant fluid is delivered to the device packages 201 and returned therefrom as a liquid, whereby the coolant source 110 may comprise a heat exchanger or chiller to maintain the coolant fluid at a desired temperature. In other embodiments, the coolant fluid may be delivered to the device packages 201 as a liquid, vaporized to a vapor within the device packages 201, and returned to the coolant source 110 as a vapor. In those embodiments, the device packages 201 may be fluidly coupled to the coolant source 110 in parallel, and the coolant source 110 may include or further include a compressor (not shown) for condensing the received vapor to a liquid form.

FIG. 2B is a schematic partial sectional side view of a portion of the system panel 100 of FIG. 2A. As shown, each device package 201 is fluidly coupled to the plurality of coolant lines 108 and is disposed in a socket 114 of the PCB 102 and connected thereto using a plurality of pins 116, or by other suitable connection methods, such as solder bumps (not shown). The device package 201 may be seated in the socket 114 and secured to the PCB 102 using a mounting frame 106 and a plurality of fasteners 112, e.g., compression screws, collectively configured to exert a relatively uniform downward force on the upward facing edges of the device package 201. The uniform downward force ensures proper pin contact between the device package 201 and the socket 114.

FIG. 2C is a schematic exploded isometric view of an example device package 201, in accordance with embodiments of the present disclosure. Generally, the device package 201 includes a package substrate 202, an integrated cooling assembly 203 disposed on the package substrate 202, and a package cover 208 disposed on a peripheral portion of the package substrate 202. Suitable materials that may be used in the package cover 208 include copper, aluminum, metal alloys, etc. The package cover 208 extends over the integrated cooling assembly 203 so that the integrated cooling assembly 203 is disposed between the package substrate 202 and the package cover 208. The integrated cooling assembly 203 includes an MCM assembly 205 and a cold plate 206 bonded to the MCM assembly 205 which includes more than one semiconductor device. The MCM assembly 205 is described in more detail in relation to FIG. 2E.

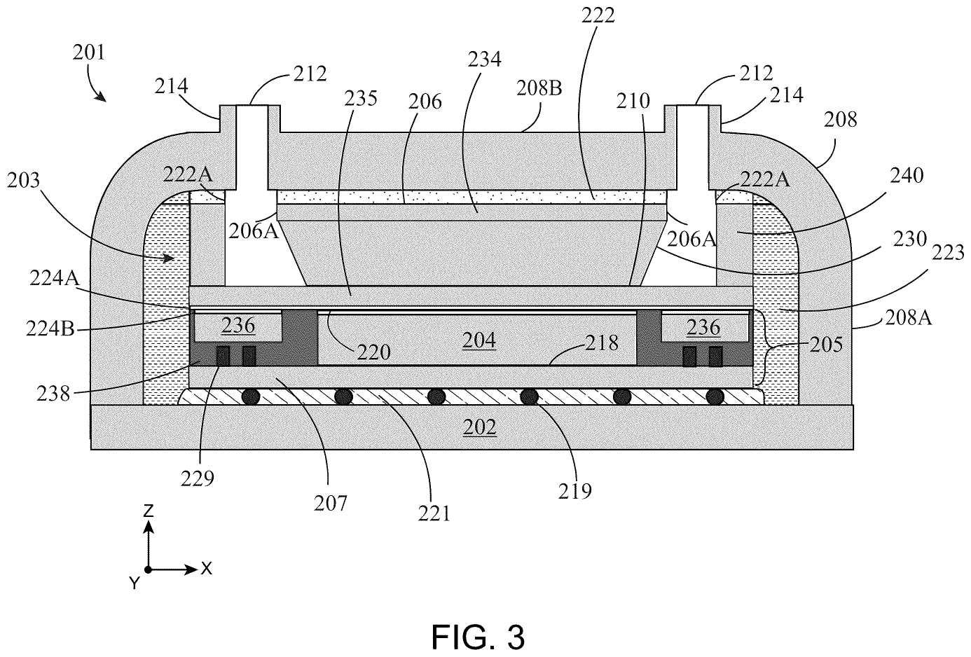

As shown, the device package 201 further includes a sealing material layer 222 that forms a coolant fluid impermeable barrier between the package cover 208 and the integrated cooling assembly 203 that prevents leaking of the coolant fluid outside of the cooling assembly and prevents coolant fluid from reaching an active side 218 (discussed below in relation to FIG. 3) of the semiconductor device 204 and causing damage thereto. In some embodiments, the sealing material layer 222 comprises an adhesive material that reliably attaches the package cover 208 to the integrated cooling assembly 203. In some embodiments, the sealing material layer 222 comprises a polymer or epoxy material that extends upwardly from the package substrate 202 to encapsulate and/or surround at least a portion of the semiconductor device 204. In some embodiments, the sealing material layer 222 may also comprise conductive material, e.g., solder. In other embodiments, the sealing material layer 222 is formed from a molding compound, e.g., a thermoset resin, that when polymerized, forms a hermetic seal between the package cover 208 and the cold plate 206. Here, the coolant fluid is delivered to the cold plate 206 through openings 222A disposed through the sealing material layer 222. As shown, the openings 222A are respectively in registration and fluid communication with inlet and outlet openings 212 of the package cover 208 thereabove and inlet and outlet openings 206A in the cold plate 206 therebelow.

It will be understood that the openings are shown in a section view. The openings may have any cross-sectional shape that allows fluid to flow therethrough (e.g., rectangular, square, hexagonal or circular cross-sections). For example, the inlet and outlet openings 206A of the cold plate 206 may form an elongated shape extending from one side of the cold plate 206 to another side of the cold plate 206. For example, the inlet and outlet openings 206A may form any shape having a length greater than a width in the X-Y plane (e.g., a rectangular or a trapezoidal shape). A shape in the X-Y plane of the openings 222A disposed through the sealing material layer 222 may be substantially the same as the shape of the inlet and outlet openings 206A of the cold plate 206 in the same place. Furthermore, it will be understood that references to an opening throughout the present disclosure refer to an opening defined by a sidewall (e.g., opening sidewall), unless otherwise indicates.

In some embodiments, gaps formed between the inside walls of the package cover 208 and the integrated cooling assembly 203 may be filled (partially or completely) with a molding material 223. The molding material 223 may encapsulate the integrates cooling assembly 203 to improve structural stability, for example.

The package substrate 202 can include a rigid material, such as an epoxy or resin-based laminate, that supports the integrated cooling assembly 203 and the package cover 208. The package substrate 202 may include conductive features disposed in or on the rigid material that electrically couples the integrated cooling assembly 203 to a system panel, such as the PCB 102.

FIG. 2D shows a top view 211 of the cold plate 206 with openings 206A, and a bottom view 213 of an upper portion of the cold plate 206 from base plate 235 (e.g., bottom portion, cover plate). The bottom view 213 shows coolant channels 210 separated by cavity dividers 230, and the sidewalls 240 of the cold plate 206.

FIG. 2E shows top views 215 and 217 and a side view 225 of an MCM assembly 205. The top view 215 shows inlets and outlets 206A of cold plate 206 (not labeled in FIG. 2E, e.g., as shown in FIG. 2C) superimposed on the MCM assembly 205. The top view 217 shows channels 210 superimposed on the MCM assembly 205. The MCM assembly 205 may include semiconductor devices 204, 242, 243, 244, 245, 246 and 247 and a silicon preform 236 disposed in an insulating layer or a mold compound 238 on a first side (e.g., top surface) of a substrate 207. A second side of substrate 207 (e.g., bottom surface) may include conductive bumps 219. In some embodiments, the substrate 207 may be an interposer or a package substrate. The substrate 207 may comprise interconnects and vias, and enable electrical connection between the semiconductor devices and to the second side of the substrate 207. The cold plate 206 of the integrated cooling assembly 203 may be bonded to one or more or all of the semiconductor devices 204, 242, 243, 244, 245, 246 and 247 (e.g., dielectric layer 224B on backside of the semiconductor devices). In some embodiments, the dielectric layer 224B may be coated over the silicon preform 236 and the mold compound 238. Although the lateral dimensions (or footprint) of the cold plate 206 are shown to be the same or similar to the lateral dimensions (or footprint) of the MCM assembly 205, the footprint of the cold plate 206 may be smaller or larger in one or both directions when compared to the footprint of the MCM assembly 205. The MCM assembly 205 may include a semiconductor device 204 (e.g., GPU, CPU, processor, etc.) and semiconductor devices 242, 243, 244, 245, and 247 (e.g., HBMs). In some embodiments, the MCM assembly 205 may be similar to the MCM assembly 830 of FIG. 8, and the semiconductor device 204, the silicon preform 236, mold compound 238, and substrate 207 (as shown in FIG. 3) may correspond to semiconductor device or chip 801, the silicon preform 820, mold compound 812, and substrate 810 of FIG. 8.

FIG. 3 is a schematic sectional view in the X-Z plane of the device package 201 taken along line A-A′ of FIG. 2C. As illustrated in FIG. 3, the semiconductor device 204 includes the active side 218 that includes device components, e.g., transistors, resistors, and capacitors, formed thereon or therein, and a non-active side, here the semiconductor device backside 220, opposite the active side 218. As shown, the active side 218 is positioned adjacent to and facing towards a substrate 207 (e.g., interposer). In some embodiments, the substrate 207 may be a package substrate, an active die, or a passive die (e.g., interposer). The active side 218 may be hybrid bonded to the substrate 207. In some embodiments, the active side 218 may be electrically connected to the substrate 207 by use of conductive bumps encapsulated by an underfill layer. The active side 218 may be electrically connected to the substrate 207 which may be electrically connected to package substrate 202 by use of conductive bumps 219, which are encapsulated by a first underfill layer 221 disposed between the substrate 207 and the package substrate 202. The first underfill layer 221 may comprise a cured polymer resin or epoxy, which provides mechanical support to the conductive bumps 219 and protects against thermal fatigue. In some embodiments, the package device 201 may not include the substrate 207 and the active side 218 may be directly electrically connected to substrate 202 using hybrid bonding or conductive bumps 219. The package substrate 202 may be a semiconductor substrate, a semiconductor interposer, a glass substrate, a glass interposer, a PCB or a combination thereof. The cold plate 206 may be disposed above the package substrate 202 with the semiconductor device 204 disposed therebetween. For example, the semiconductor device 204 (and the first underfill layer 221) may be disposed between the cold plate 206 and the package substrate 202. In some embodiments, the cold plate 206 may be disposed directly on the package substrate 202.

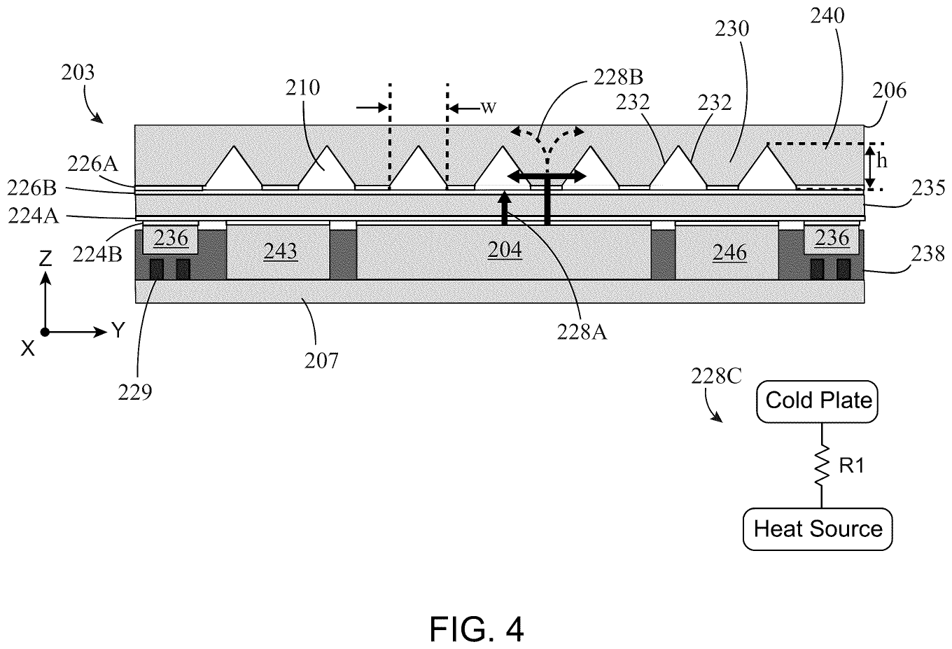

Here, the cold plate 206 comprises a top portion 234 and a sidewall 240 (e.g., a perimeter sidewall defining a perimeter of the cold plate 206) extending downwardly from the top portion 234 to a base plate 235 (e.g., bottom portion, cover plate) of the cold plate 206. The top portion 234, the perimeter sidewall 240, and a backside (e.g., top side) of a base plate 235 of the cold plate 206 collectively define a coolant channel 210 therebetween. A thickness of a base plate 235 may be optimized for a particular situation. For example, a thicker base plate may help spread the heat in some cases (e.g., at certain temperatures, where the heat is not too high). The cold plate 206 comprises cavity dividers 230 extending downwardly from the top portion 234 towards the base plate 235 of the cold plate 206. The cavity dividers 230 may alternatively be referred to as support features 230, which provide structural support to the integrated cooling assembly 203. The cavity dividers 230 may extend laterally and in parallel between an inlet opening 206A of the cold plate 206 and an outlet opening 206A of the cold plate 206 to define plural coolant channels 210 therebetween. It should be appreciated that, the cold plate 206 may comprise one cavity divider 230 which forms two coolant channels (e.g., one coolant channel on either side of the cavity divider 230) by means of the cavity divider 230 and portions of the perimeter sidewall 240. More specifically, coolant channels 210 may be formed between the cavity divider 230 and a portion of the perimeter sidewall 240 extending parallel to or in the same general direction as the cavity divider 230. Alternatively, in other embodiments, the cold plate 206 may comprise plural cavity dividers 230, for example two cavity dividers, five cavity dividers, or six cavity dividers (as illustrated in FIG. 4). In such examples, the cold plate 206 comprises more than two coolant channels 210, for example three coolant channels, four coolant channels, seven coolant channels, or more, defined between the cavity dividers 230 and/or the cavity divider(s) 230 and the perimeter sidewall 240. In some embodiments, at least one of the cavity dividers 230 may extend discontinuously between the inlet opening 206A and the outlet opening 206A (in the X-axis direction) to form a discontinuous cavity divider. A discontinuous cavity divider may be formed of plural segments between which coolant fluid may flow. The segments of a discontinuous cavity divider may have the same or different lengths in the X-axis direction. One or more segments may form a post.

The cavity dividers 230 comprise cavity sidewalls 232 (as illustrated in FIG. 4) which form surfaces of corresponding coolant channels 210. In embodiments where plural cavity dividers 230 extend in parallel to each other, cavity sidewalls 232 of adjacent cavity dividers 230 are opposite (e.g., facing) each other. In embodiments comprising a single cavity divider 230, a first cavity sidewall may be opposite (e.g., face) a first portion of the perimeter sidewall 240 extending parallel to and facing the first cavity sidewall. A second cavity sidewall may be opposite (e.g., face) a second portion of the perimeter sidewall 240 extending parallel to and facing the second cavity sidewall. The first portion of the perimeter sidewall 240 may be an opposite side of the cold plate 206 to the second portion of the perimeter sidewall 240. For example, in embodiments where the cold plate 206 is rectangular, first and second opposing sides of the rectangular cold plate 206 form the first and second portions of the perimeter sidewall 240.

The cavity dividers 230 may be continuous cavity dividers which extend continuously (e.g., in the X-axis direction) between the inlet opening 206A and the outlet opening 206A of the cold plate 206.

With reference to FIG. 3, coolant channels 210 may be defined by:
the backside (e.g., top side) of the base plate 235 (e.g., bottom portion, cover plate) of the cold plate 206, which forms lower coolant channel surfaces;
portions of the perimeter sidewall 240 extending in the Y-axis direction, which form end surfaces of the coolant channels 210;
the cavity sidewalls 232, which form inner surfaces of the coolant channels 210 in the X-axis direction; and
portions of the perimeter sidewall 240 extending in the X-axis direction, which form outer surfaces of the coolant channels 210 in the X-axis direction.

As shown in FIG. 4 and described in further detail below, a cold plate 206, the cavity sidewalls 232 can be formed at an acute angle with respect to the backside of the base plate 235 such that upper portions of opposing (e.g., facing) cavity sidewalls 232 meet. Therefore, the cavity sidewalls 232 and the backside of the base plate 235 collectively define a triangular cross-section of the coolant channel 210. However, it will be understood that the coolant channel 210 may be formed with different shaped cross-sections. For example, one or more coolant channels may be formed with trapezoidal, rectangular, or semi-circular cross-section, or elliptical or parabolic or a combination thereof.

In some embodiments, the backside of the base plate 235 comprises a corrosion protective layer (not shown). The corrosion protective layer may be a continuous layer disposed across the entire backside of the base plate 235, such that an upper part of the cold plate 206 is attached thereto. Beneficially, the corrosion protective layer provides a corrosion-resistant barrier layer, thus preventing undesired corrosion of the base plate 235 (e.g., the semiconductor substrate material which might otherwise be in direct contact with coolant fluid flowing through a coolant chamber volume 210).

One or more coolant chamber volumes may include one or more coolant channels. The coolant channels may extend between a single inlet opening and a single outlet opening of the cold plate 206, such that the coolant chamber volume(s) and/or coolant channel(s) share the same inlet and outlet openings. In other embodiments, multiple inlet and/or outlet openings may be coupled to the coolant chamber volume(s).

In embodiments having plural coolant chamber volumes and/or plural coolant channels, each coolant chamber volume and/or coolant channel may be connected between a separate inlet opening and a separate outlet opening. In such embodiments, the coolant fluid may be directed to the separate inlet openings and from the separate outlet openings using a manifold disposed above the openings in the Z-axis direction. In some embodiments, a gasket may be used to seal a gap between the manifold and the cold plate inlet/outlet openings. The gasket may be made of particulate reinforced or unreinforced elastomer or rubber (e.g., neoprene, nitrile, ethylene propylene diene monomer, or silicon rubber) or similar such material. For example, the gasket may be an o-ring. The gasket may be attached between a lower surface of the manifold and an upper surface of the cold plate facing the manifold using an adhesive. The gasket may provide a water tight seal to direct coolant fluid from the manifold into the cold plate inlet/outlet openings while preventing coolant fluid from leaking onto exterior surfaces of the integrated cooling assembly 203. In some embodiments, the manifold is attached to one or more cold plates using one or more corresponding gaskets.

Referring to FIG. 4, a height h in the Z-axis direction of the coolant chamber volume(s) and or coolant channel(s) may be greater than 100 μm, 100 μm-1000 μm, or 100 μm-700 μm. A width w in the Y-axis direction of each coolant channel 210 may be greater than 100 μm, 100 μm-1000 μm, or 100 μm-700 μm. For example, the width of each coolant channel 210 may be greater than the height h thereof. In some embodiments, the width w of a coolant channel 210 may, at the widest portion, which may be taken as a base of the triangular shape of the coolant chamber channels 210 shown in FIG. 4, range from 0.2 mm to 5 mm. More specifically, the width w of a coolant channel 210 may range from 0.5 to 1.5 mm. The width w of the coolant chamber volumes(s) and/or coolant channel(s) may also be between 1 and 5 mm.

A cross-section of the coolant chamber volume(s) and/or coolant channel(s) in the Y-Z plane is wide enough to allow for a pressure drop of 0-20 psi, 3-15 psi, or 4-10 psi.

In some embodiments, preparing a desired surface roughness of the sidewalls of the coolant chamber volume(s) and/or coolant channels may include depositing an organic layer on a photoresist layer after cold plate features have been etched to form a micro-masking layer, such as between 1 to 30 nm. The micro-masking layer may be dry etched to form the desired surface roughness, such as between 0.1 to 3.0 nm. Advantageously, providing sidewalls with surface roughness increases the likelihood of fluid being directed towards and contacting the backside 220 of the semiconductor device 204 (e.g., by disrupting a hydrodynamic boundary layer of fluid between the sidewall and the coolant fluid).

With reference to FIGS. 3 and 4, the cold plate 206 is attached to the backside 220 of the device 204 without the use of an intervening adhesive. For example, the cold plate 206 may be directly bonded to the backside 220 of the device 204, such that the cold plate 206 and the backside 220 of the device 204 are in direct contact. For example, in some embodiments, one or both of the cold plate 206 and the backside of the MCM assembly 205 (e.g., backside 220 of the semiconductor device 204 and the silicon preform 236) may comprise a dielectric material layer, e.g., a first dielectric material layer 224A and a second dielectric material layer 224B respectively, and the cold plate 206 is directly bonded to the backside 220 of the semiconductor device 204 through bonds formed between the dielectric material layers 224A, 224B. In some embodiments, one of the cold plate 206 or the backside of the MCM assembly 205 (e.g., backside 220 of the semiconductor device 204 and the silicon preform 236) may comprise a thin bonding dielectric layer (e.g., silicon nitride, etc.) and other element(s) may not include any such explicit bonding dielectric layer (or can have only a native oxide layer). The first and second dielectric material layers 224A, 224B may be continuous or non-continuous. For example, the first dielectric material layer 224A may be disposed only on lower surfaces of the cold plate 206 (e.g., base plate 235) facing the backside 220 of the semiconductor device 204. With reference to FIGS. 3 and 4, portions of the first dielectric material layer 224A may be disposed only on lower surfaces of the cold plate 206 (e.g., base plate 235). Beneficially, directly bonding a cold plate 206 the semiconductor device 204, as described above, reduces the thermal resistance therebetween and increases the efficiency of heat transfer from the semiconductor device 204 to the cold plate 206. In some embodiments the material composition of the first dielectric material layer 224A is different from that of the second dielectric material layer 224B. In some applications, the total thickness of the first dielectric material layer 224A and that of the second dielectric material layer 224B is less than 3 microns, less than 1.5 microns, less than 1 micron, or less than 0.5 micron. In some embodiments, it may be preferred that the total thickness of the first dielectric material layer 224A and that of the second dielectric material layer 224B is less than 1 micron or less than 0.5 micron.

With reference to FIG. 4, described below, portions of a first dielectric material layer 226A may be disposed only on lower surfaces of the cavity dividers 230 (e.g. support features 230) and the perimeter sidewall 240. The first and second dielectric material layers 226A, 226B may be continuous or non-continuous. For example, the first dielectric material layer 226A may be disposed only on lower surfaces of the upper portion of a cold plate 206 facing the backside 220 of the base plate 235.

FIG. 4 is a schematic sectional view in the Y-Z plane of the integrated cooling assembly 203, in accordance with embodiments of the present disclosure.

A width of a cold plate 206 in a first direction is greater than a width of a semiconductor device 204 the first direction. The first direction may be taken to be a direction perpendicular to a second direction in which perimeter sidewall extends. With reference to FIGS. 3A and 3B, the second direction is the Z-axis direction and the first direction is either the X-axis or the Y-axis direction. As shown, the width of the cold plate 206 is greater than the width of the semiconductor device 204 in both the X-axis direction and the Y-axis direction. In embodiments of FIG. 3 where the semiconductor device 204 has a rectangular footprint, the cold plate 206 may extend beyond all four sidewalls of the semiconductor device 204. However, it will be understood that the width of the cold plate 206 may be greater than the width of the semiconductor device 204 in either the X-axis direction or the Y-axis direction. In some embodiments, the semiconductor device 204 is a processor of an MCM. A silicon preform 236 and mold compound 238 may help support the inlets and outlets 206A of a cold plate 206. For example, the inlet and outlets 206A of the cold plate 206 may be outside of an active part (e.g., semiconductor device 204) and still be supported. The silicon preform 236 may help keep the part (e.g., MCM assembly) flatter during polishing so that it will not develop as much curvature in the surface, which tends to happen with smaller parts (e.g., MCM chips) on a larger underlying substrate (e.g., disposed on a wider substrate or plate).

In order to provide an upper part of the cold plate 206 having a width greater than a width of the semiconductor device 204, a structural substrate (e.g., base plate 235) having substantially the same width (in the X-axis direction and/or the Y-axis direction) as the upper part of the cold plate 206 can be provided between the upper part of the cold plate 206 and the semiconductor device 204. The structural substrate may provide structural rigidity to overhanging portions of the upper part of the cold plate 206 and also closes portions of coolant channels 210 in the overhanging portions which would otherwise be exposed. The structural substrate may be attached between the upper portion of the cold plate 206 and the semiconductor device 204 using direct bonding techniques described herein.

Advantageously, by increasing the width of the cold plate 206 in the X-axis direction and/or the Y-axis direction, as described above, additional coolant channels 210 may be introduced to the cold plate 206 in order to increase the efficiency of thermal cooling.

In some embodiments, only portions of coolant channels 210 in the overhanging portions may be closed by the structural substrate 207, while portions of coolant channels 210 vertically adjacent to the semiconductor device 204 may be exposed to a backside of the semiconductor device 204. For example, portions of coolant channels 210 vertically adjacent to the semiconductor device 204 may be exposed by etching openings in horizontally aligned portions of the structural substrate.

FIG. 4 is a schematic sectional view in the Y-Z plane of an embodiment of the integrated cooling assembly 203, with a cold plate. The cold plate 206 comprises a first part (e.g., upper part) and a second part (e.g., lower part or base plate 235). The first part has a patterned side that faces towards a base plate 235 and the semiconductor device 204 and an opposite side that faces towards the package cover 208 (not shown). The patterned side comprises a coolant chamber volume having plural coolant channels 210, which extend laterally (along the X-axis direction in FIG. 4) between the inlet and outlet openings of the cold plate 206. Each coolant channel 210 comprises cavity sidewalls that define a corresponding coolant channel 210. Portions of the first part of the cold plate 206 between the cavity sidewalls 232 form the support features 230 (e.g., cavity dividers 230). The support features 230 (e.g., cavity dividers 230) provide structural support to the integrated cooling assembly 203 and disrupt laminar fluid flow (e.g., due to surface roughness of the sidewalls) at the interface of the coolant and the backside of the base plate 235, resulting in increased heat transfer therebetween. Furthermore, by introducing plural coolant channels 210 to define separate coolant flow paths, an internal surface area of the cold plate 206 is increased, which further increases the efficiency of heat transfer.

In FIG. 4, arrows 228A and 228B illustrate two different heat transfer paths in the integrated cooling assembly 203. A first heat transfer path illustrated by arrow 228A shows heat generated by the semiconductor device 204 transferring from the semiconductor material of the semiconductor device 204 to semiconductor material (e.g., silicon material) of the cold plate 206 structure (e.g., a base plate 235) to coolant fluid flowing through the cold plate 206. A second heat transfer path illustrated by arrows 228B shows heat generated by the semiconductor device 204 being transferred from semiconductor material (e.g., silicon material) of the semiconductor device 204 to semiconductor material (e.g., silicon material) of the cold plate 206 structure (e.g., a base plate 235), propagated throughout the semiconductor material of the cold plate 206 structure (shown as dashed lines), and being transferring into coolant fluid flowing through the cold plate 206. A thermal resistance of the first and second heat transfer paths 228A, 228B is illustrated by heat transfer path 228C, which is shown as thermal resistance R1 between a heat source and a cold plate. Here, R1 is the thermal resistance of the bulk semiconductor material of the semiconductor device 204. It can be seen that the heat transfer path 228C of the integrated cooling assembly 203 is reduced compared to the heat transfer path 26 of the device package 10 of FIG. 1, due to the direct bonding discussed above. For example, heat transfer path 228C may be from the semiconductor device 204 to the cold plate 206 (e.g., semiconductor material of the cold plate such as the base plate 235 or a top portion of the cold plate 206 or to coolant fluid flowing through cold plate 206) whereas heat transfer path 26 of FIG. 1 may be from the heat source (e.g., device 14) to multiple components (e.g., TIM layer 16A to heat spreader 18 to TIM layer 20) before going to the heat sink 22.

In some embodiments, the cold plate 206 may be attached to the semiconductor device 204 using a hybrid bonding technique, where bonds are formed between the dielectric material layers 224A, 224B and between metal features, such as between first metal pads and second metal pads, disposed in the dielectric material layers 224A, 224B. Advantageously, by using hybrid bonding techniques, interconnections may be formed between the cold plate 206 and the semiconductor device 204 using the first and second metal pads.

Suitable dielectrics that may be used as the dielectric material layers 224A, 224B and 226A, 226B include silicon oxides, silicon nitrides, silicon oxynitrides, silicon carbon nitrides, metal-oxides, metal-nitrides, silicon carbide, silicon oxycarbides, silicon oxycarbonitride, diamond-like carbon (DLC), or combinations thereof. In some embodiments, one or both of the dielectric material layers 224A, 224B and 226A, 226B are formed of an inorganic dielectric material, e.g., a dielectric material substantially free of organic polymers. Typically, one or both of the dielectric layers are deposited to a thickness greater than the thickness of a native oxide, such as about 1 nanometer (nm) or more, 5 nm or more, 10 nm or more, 50 nm or more, or 100 nm or more. In some embodiments, one or both of the layers are deposited to a thickness of 3 micrometers or less, 1 micrometer or less, 500 nm or less, such as 100 nm or less, or 50 nm or less. The dielectric layer material and thickness may be optimized for lower thermal resistance between the semiconductor device and the cold plate.

The cold plate 206 may be formed of any suitable material that has sufficient structural strength to withstand the desired pressures of coolant flowing into the coolant chamber volume 210. For example, the cold plate 206 may be formed of semiconductor material like silicon or other materials like glass. In other examples, the cold plate 206 may be formed of a material selected from a group comprising polymers, metals, ceramics, or composites thereof. In some embodiments, the cold plate 206 may be formed of stainless steel (e.g., from a stainless steel metal sheet) or a sapphire plate. In some embodiments, the top surface of the cold plate 206 may be coated with a conductive material (not shown), such that the cold plate also serves a shield, shielding the devices 236, 243, 204, 246 and 236 from interfering radiation for example electromagnetic radiation.

In some embodiments, the cold plate 206 may be formed of a bulk material having a substantially similar CTE to the bulk material of the substrate 202 and/or the semiconductor device 204, where the CTE is a fractional change in length of the material (in the X-Y plane) per degree of temperature change. In some embodiments, the CTEs of the cold plate 206, the substrate 202, and/or the semiconductor device 204 are matched so that the CTE of the substrate 202 and/or the semiconductor device 204 is within about +/−20% or less of the CTE of the cold plate 206, such as within +/−15% or less, within +/−10% or less, or within about +/−5% or less when measured across a desired temperature range. In some embodiments, the CTEs are matched across a temperature range from about −60° C. to about 100° C. or from about-60° C. to about 175° C. In one example embodiment, the matched CTE materials each include silicon.

In some embodiments, the cold plate 206 may be formed of a material having a substantially different CTE from the semiconductor device 204, e.g., a CTE mismatched material. In such embodiments, the cold plate 206 may be attached to the semiconductor device 204 by a compliant adhesive layer (not shown) or a molding material that absorbs the difference in expansion between the cold plate 206 and the semiconductor device 204 across repeated thermal cycles. In some embodiments, where the cold plate 206 may be formed of a material having a substantially different CTE from the semiconductor device 204, the bottom of the cold plate may be coated with a suitable dielectric layer (for example SiN) as a portion of the first dielectric material layer 226A. The cold plate 206 can be directly bonded to the second dielectric material 226B on the base plate 235. In some embodiments, the cold plate 206 and the base plate 235 may comprise of similar conductive materials having a CTE higher than at least one of the semiconductor devices 204.

The package cover 208 shown in FIGS. 2C and 3 generally comprises one or more vertical or sloped sidewall portions 208A and a lateral portion 208B that spans and connects the sidewall portions 208A. The sidewall portions 208A may extend upwardly from a peripheral surface of the package substrate 202 to surround the device 204 and the cold plate 206 disposed thereon. The lateral portion 208B may be disposed over the cold plate 206 and is typically spaced apart from the cold plate 206 by a gap corresponding to the thickness of the sealing material layer 222. The sealing material may be an adhesive or a gasket. In some embodiments, instead of or as well as the sealing material layer 222, a gasket may be used to seal a gap between the package cover 208 and the cold plate inlet/outlet openings. The gasket may be made of reinforced or unreinforced elastomer or rubber (e.g., neoprene, nitrile, ethylene propylene diene monomer, or silicon rubber) or similar such material. For example, the gasket may be an o-ring. The gasket may be attached between a lower surface of the package cover 208 and an upper surface of the cold plate facing the package cover 208 using an adhesive. The gasket may provide a water tight seal to direct coolant fluid from the package cover 208 into the cold plate inlet/outlet openings while preventing coolant fluid from leaking onto exterior surfaces of the integrated cooling assembly 203. In some embodiments, the package cover 208 is attached to one or more cold plates using one or more corresponding gaskets.

Coolant is circulated through the coolant chamber volume 210 through the inlet and outlet openings 212 of the package cover 208 formed through the lateral portion 208B. The inlet and outlet openings 206A of the cold plate 206 may be in fluid communication with the inlet and outlet openings 212 of the package cover 208 through the inlet and outlet openings 222A formed in the sealing material layer 222 disposed therebetween. In certain embodiments, coolant lines 108 (FIGS. 2A-2B) may be attached to the device package 201 by use of connector features formed in the package cover 208, such as threads formed in the sidewalls of the inlet and outlet openings 212 of the package cover 208 and/or protruding features 214 that surround the inlet and outlet openings 212 and extend upwardly from a surface of the lateral portion 208B.

Typically, the package cover 208 is formed of semi-rigid or rigid material so that at least a portion of the downward force exerted on the package cover 208 by the mounting frame is transferred to a supporting surface of the package substrate 202 and not transferred to the cold plate 206 and the semiconductor device 204 therebelow. In some embodiments, the package cover 208 is formed of a thermally conductive metal, such as aluminum or copper. In such embodiments, the package cover 208 functions as a heat spreader that redistributes heat from one or more electronic components of the semiconductor device 204. In some embodiments, the package cover 208 and/or a manifold (such as the manifold discussed above) may consist of or comprise a thermally insulating material or materials. In such embodiments, the package cover 208 and/or the manifold may function as a thermal insulator to retain heat or cold. In some embodiments, the package cover 208 and/or the manifold may be insulating to minimize or reduce the flow of thermal energy (e.g., thermal flux) between components (e.g., semiconductor devices, semiconductor device stacks, device packages, etc.). For example, the package cover 208 and/or the manifold may minimize or reduce the flow of thermal energy between a first semiconductor device and a second semiconductor device. In another example, the package cover 208 and/or the manifold may minimize or reduce the flow of thermal energy between a first semiconductor device stack and a second semiconductor device stack. In another example, the package cover 208 and/or the manifold may minimize or reduce the flow of thermal energy between a first device package and a second device package. In another example, the package cover 208 and/or the manifold may minimize or reduce the flow of thermal energy between a semiconductor device and a semiconductor device stack. In another example, the package cover 208 and/or the manifold may minimize or reduce the flow of thermal energy between a semiconductor device of a device package and a second device package.

It should be noted that the direction in which the coolant fluid flows through the cold plate 206 may be controlled depending on the relative locations of the inlet and outlet openings. For example, the coolant fluid may flow from left to right in the device package 201 of FIG. 3 when the inlet openings 212, 222A, 206A of the package cover 208, the sealing material layer 222, and the cold plate 206, respectively, are located on the left-hand side of the device package 201 and the outlet openings 212, 222A, 206A of the package cover 208, the sealing material layer 222, and the cold plate 206, respectively, are located on the right-hand side of the device package 201. Alternatively, the coolant fluid may flow from right to left in the device package 201 illustrated in FIG. 3 when the outlet openings 212, 222A, 206A of the package cover 208, the sealing material layer 222, and the cold plate 206 are located on the left-hand side of the device package 201 and the inlet openings 212, 222A, 206A of the package cover 208, the sealing material layer 222, and the cold plate 206 are located on the right-hand side of the device package 201. Although only one set of inlet and outlet openings is shown and described here, additional inlet and outlet openings may also be provided at various locations on the package cover 208, the sealing material layer 222, and the cold plate 206.

An example flow path of the coolant fluid through the coolant chamber volume 210 may be as follows:
1. Coolant fluid enters the coolant chamber volume 210 through the inlet openings 212, 222A, and 206A.
2. Coolant fluid flows across the inside surfaces of the cold plate 206 and absorbs heat generated by the semiconductor device 204, which has dissipated into the cold plate 206 structure. The coolant fluid may also flow directly across the backside 220 of the semiconductor device 204 to absorb heat energy directly from the semiconductor device 204. The coolant chamber volume 210 may additionally have various channels formed to direct the coolant fluid flow from inlet opening(s) to outlet opening(s) and facilitate heat extraction from the semiconductor device 204 by the coolant fluid. In some embodiments, the coolant fluid may be in direct contact with the backside 220 of the semiconductor device 204 or via one or more substrate or layers between the coolant fluid or backside 220 of the semiconductor device 204.
3. Coolant fluid exits the coolant chamber volume 210 through outlet openings 212, 222A, and 206A.

It will be understood from the above flow path that heat is extracted without introducing an unnecessary thermal resistance (e.g., a TIM disposed between the backside 220 of the semiconductor device 204 and the cold plate 206) between the backside 220 of the semiconductor device 204 and the cold plate 206.

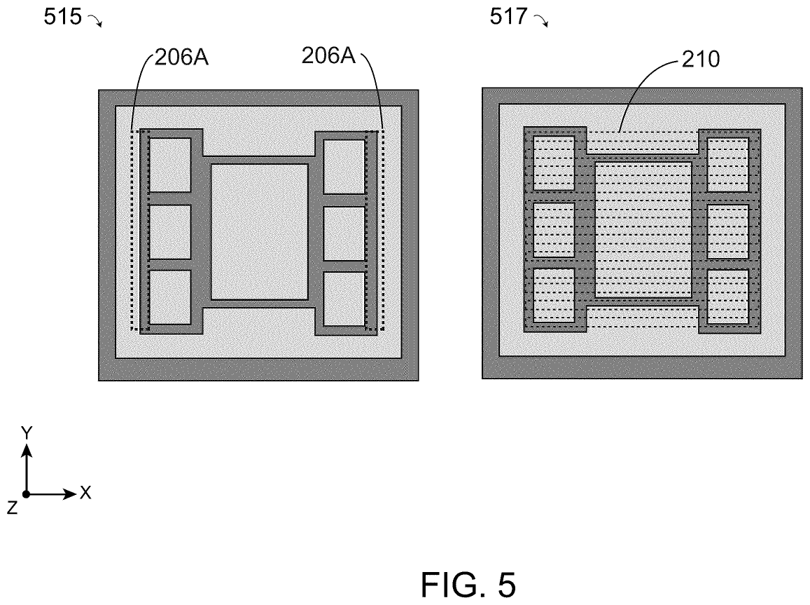

FIG. 5 shows a top view 515 and 517 of an MCM assembly. In some embodiments, the MCM assembly shown in FIG. 5 corresponds to the MCM assembly shown in FIG. 2E, except the MCM assembly is rotated 90 degrees before attaching the cold plate 206. In top view 515, the inlets and outlets 206A of cold plate 206 is superimposed. In top view 517, the channels 210 are superimposed.

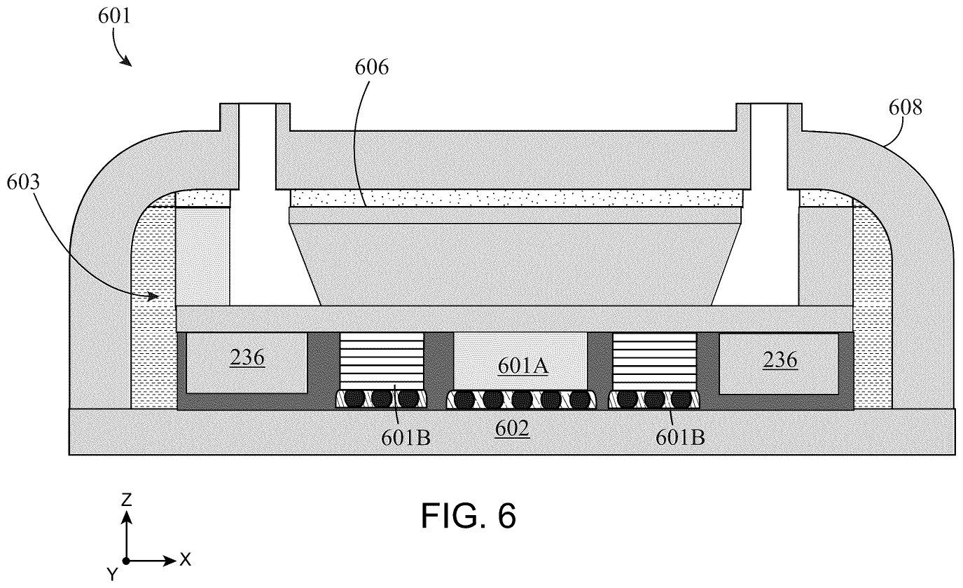

FIG. 6 is a schematic side sectional view in the X-Z plane of an example of a multi-component device package 601 that includes a cold plate 606 (e.g., similar to cold plate 206 of FIG. 2E) directly bonded to the backside surfaces of two or more devices 601A, 601B. The multi-component device package 601 may be similar to the device package 201 described above, and therefore the description of similar features is omitted for brevity. In some embodiments, the two or more devices 601A and 601B are singulated from reconstituted wafers and then bonded to the cold plate 606. As shown, the device package 601 includes a package substrate 602, an integrated cooling assembly 603 and a package cover 608. The integrated cooling assembly 603 may include a plurality of devices 601A (one shown) that may be singulated and/or disposed in a vertical device stack 601B (two shown). The cold plate 606 may be attached to each of the devices 601A and device stacks 601B, e.g., by the direct bonding methods described herein or other methods including adhesive. In some embodiments, the device 601A may comprise a processor, and the device stacks 601B may each comprise a plurality of memory devices, such as a high bandwidth memory (HBM) comprising a bottom logic die and a plurality of memory (e.g., DRAM) dies stacked on the logic die. Here, the device 601A and the device stacks 601B are disposed in a side-by-side arrangement on the package substrate 602 and are in electrical communication with one another through conductive elements formed in, on, or through the package substrate 602. Here, the cold plate 606 is sized to provide a bonding surface for attachment to the device 601A and the device stacks 601B but may otherwise be the same or substantially similar to other cold plates described herein. In some embodiments, the lateral dimensions (or footprint) of the cold plate 606 may be smaller or larger than the combined lateral dimensions (or footprint) of the device 601A and the device stacks 601B. In some embodiments, one or more sidewalls of the cold plate 606 may be aligned or offset to the vertical sidewalls of the device 601A and the device stacks 601B (including inside or outside their footprint). In some embodiments, more than one cold plate 606 may be bonded. For example, separate cold plates may be bonded to the device 601A and the device stacks 601B. In some embodiments, a channel of a cold plate may be directly exposed to a backside of the device 601A and the device stacks 601B.

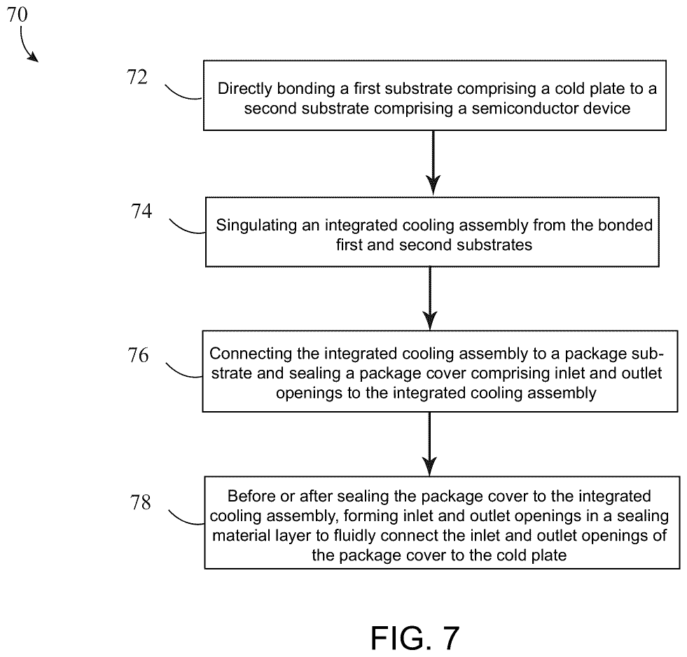

FIG. 7 is a flow diagram showing a method 70 of forming an integrated cooling assembly, according to embodiments of the present disclosure. Generally, the method 70 includes bonding a first substrate comprising one or more cold plates 206 to a second substrate comprising one or more semiconductor devices 204, and singulating one or more integrated cooling assemblies 203 from the bonded first and second substrates. For example, a wafer (bare or reconstituted wafer) comprising one or more cold plates 206 can be directly bonded to another wafer (bare or reconstituted wafer) comprising one or more semiconductor devices 204.

It will be understood that the first substrate may be a cold plate die or part of a wafer of cold plates. Further, the second substrate may be a semiconductor device die or part of a wafer of semiconductor devices 204. Therefore, the method 70 may include die-to-die direct bonding (e.g., cold plate die to semiconductor device die), wafer-to-die direct bonding (e.g., cold plate die to semiconductor device wafer, or cold plate wafer to semiconductor device die), and wafer-to-wafer direct bonding (e.g., cold plate wafer to semiconductor device wafer). It will be understood that the singulation step (discussed in relation to block 74, below) may not be required for a die-to-die direct bonding operation.

For simplicity, the following description is focused on forming one integrated cooling assembly 203 comprising one cold plate 206 and one semiconductor device 204. However, as mentioned above, in some embodiments, the first substrate may comprise plural cold plates 206 and the second substrate may comprise plural semiconductor devices 204, such that plural integrated cooling assemblies 203 may be formed from the first and second substrates. In some embodiments, the integrated cooling assembly or assemblies 203 may comprise at least one cold plate 206 and at least one MCM assembly 205.

At block 72, the method 70 includes directly bonding the first substrate (e.g., a monocrystalline silicon wafer) comprising a cold plate 206 to the second substrate (e.g., a monocrystalline silicon wafer) comprising a semiconductor device 204. By direct bonding, it is meant that the bond is effected without an intervening adhesive. In some embodiments, the first substrate comprises at least one cold plate 206 and the second substrate comprises at least one MCM.

In some embodiments, the first substrate may be etched using a patterned mask layer formed on its surface to form features of the cold plate 206. An anisotropic etch process may be used, which uses inherently differing etch rates for the silicon material as between {100} plane surfaces and {111} plane surfaces when exposed to an anisotropic etchant.

In some embodiments, the etching process is controlled to where a ratio of the etch rate in the {100} plane to the etch rate in the {111} plane is between about 1:10 and about 1:200, such as between about 1:10 and about 1:100, for example between about 1:10 and 1:50, or between about 1:25 and 1:75. Examples of suitable anisotropic wet etchants include aqueous solutions of potassium hydroxide (KOH), ethylene diamine and pyrocatechol (EPD), ammonium hydroxide (HN₄OH), hydrazine (N₂H₄), or tetra methyl ammonium hydroxide (TMAH). The actual etch rates of the silicon substrate depend on the concentration of the etchant in the aqueous solution, the temperature of the aqueous solution, and a concentration of the dopant in the substrate (if any). Typically, the mask layer is formed of a material that is selective to anisotropic etch compared to the underlying monocrystalline silicon substrate. Examples of suitable mask materials include silicon oxide (SixOy) or silicon nitride (SixNy). In some embodiments, the mask layer has a thickness of about 100 nm or less, such as about 50 nm or less, or about 30 nm or less. In some embodiments, the mask layer has a thickness of about 1000 nm or less, such as about 500 nm or less, or about 300 nm or less. The mask layer may be patterned using any suitable combination of lithography and material etching patterning methods.

The second substrate may include a bulk material, and a plurality of material layers disposed on the bulk material. The bulk material may include any semiconductor material suitable for manufacturing semiconductor devices, such as silicon, silicon carbide, silicon germanium, germanium, group III-V semiconductor materials, group II-VI semiconductor materials, or combinations thereof. While some high-performance processors like CPUs, GPUs, neural processing units (NPUs), and tensor processing units (TPUs) are typically made out of silicon, some other high power density (hence substantial heat-generating) devices may comprise silicon carbide or gallium nitride, for example. In some embodiments, the second substrate may include a monocrystalline wafer, such as a silicon wafer, a plurality of device components formed in or on the silicon wafer, and a plurality of interconnect layers formed over the plurality of device components. In other embodiments, the second substrate may comprise a reconstituted substrate, e.g., a substrate formed from a plurality of singulated devices embedded in a support material. In some embodiments, each semiconductor device may have its own individual cold plate fabricated through a reconstitution process.

The bulk material of the second substrate may be thinned after the semiconductor device 204 is formed using one or more backgrinding, etching, and polishing operations that remove material from the backside. Thinning the second substrate may include using a combination of grinding and etching processes to reduce the thickness (in the Z-direction) to about 450 μm or less, such as about 200 μm or less, or about 150 μm or less or about 50 μm or less. After thinning, the backside 220 may be polished to a desired smoothness using a chemical mechanical polishing (CMP) process, and the dielectric material layer may be deposited thereon. In some embodiments, the dielectric material layer may be polished to a desired smoothness to prepare the second substrate for the bonding process. In some embodiments, the method 70 includes forming a plurality of metal features in the dielectric material layer in preparation for a hybrid bonding process, such as by use of a damascene process.

In some embodiments, the active side of the second substrate is temporarily bonded to a carrier substrate (not shown) before the thinning process. When used, the carrier substrate provides support for the thinning operation and/or for the thinned material to facilitate substrate handling during one or more of the subsequent manufacturing operations described herein.

Here, the method 70 may include forming dielectric layers on one or both the first and second substrates, and directly bonding includes forming dielectric bonds between a first dielectric material layer of the first substrate and a second dielectric material layer of the second substrate (or forming direct dielectric bonds between one substrate (which may have a native oxide layer at its bonding surface) and a dielectric material layer of the other substrate). In some embodiments, dielectric material layer may be grown on the chips and the silicon preform (e.g., silicon surfaces) of the second substrate (e.g., MCM assembly). Direct bonding processes join dielectric layers by forming strong chemical bonds (e.g., covalent bonds) between the dielectric layers.

Generally, directly bonding the surfaces (of the dielectric material layers formed on the first and second substrates) includes preparing, aligning, and contacting the surfaces. Examples of dielectric material layers include silicon oxide, silicon nitride, silicon oxynitride, and silicon carbonitride. Preparing the surfaces may include smoothing the respective surfaces to a desired surface roughness, such as between 0.1 to 3.0 nm RMS, activating the surfaces (e.g., a “very slight etch” using plasma or wet chemical treatment as taught in U.S. Pat. No. 6,902,987) to weaken or open chemical bonds in the dielectric material, and terminating the surfaces with a desired species (e.g., also as described in U.S. Pat. No. 6,902,987). Smoothing the surfaces may include polishing the first and second substrates using a CMP process. Simultaneously activating and terminating the surfaces with a desired species may include exposing the surfaces to radical species formed in a plasma. The bond interface between the bonded dielectric layers can include a higher concentration of materials from the activation and/or last chemical treatment processes compared to the bulk of the bonding layers. For example, in some embodiments that utilize a nitrogen plasma for activation that terminates the bonding surface with a nitrogen-containing species, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH2 molecules, yielding a nitrogen-terminated surface. In embodiments that utilize an oxygen plasma for activation, an oxygen concentration peak can be formed at the bond interface between non-conductive bonding surfaces. Such an oxygen concentration peak will be more detectable when the bonding layers do not contain oxygen, such as layers containing silicon nitride or silicon carbon nitride.

In some embodiments, the plasma is formed using a nitrogen-containing gas, e.g., N₂, and the terminating species includes nitrogen, or nitrogen and hydrogen. In some embodiments, fluorine may also be present within the plasma. In some embodiments, the surfaces may be activated using a wet cleaning or etching process, e.g., by exposing the surfaces to an aqueous ammonia solution (e.g., ammonium hydroxide). In some embodiments, the dielectric bonds may be formed using a dielectric material layer deposited on only one of the first and second substrates, but not on both. In those embodiments, the direct dielectric bonds may be formed by contacting the deposited dielectric material layer of one of the first and second substrates directly with a bulk material surface (or such a surface with a native oxide) of the other substrate.

Directly forming direct dielectric bonds between the first and second substrates at block 72 may include bringing the prepared and aligned surfaces into direct contact at a temperature less than 150° C., such as less than 100° C., for example, less than 30° C., or about room temperature, e.g., between 20° C. and 30° C. Without intending to be bound by theory, in the case of directly bonding surfaces terminated with nitrogen and hydrogen (e.g., NH2 groups), it is believed that a chemical bond is formed in part from the nitrogen species, wherein hydrogen gas byproducts (H₂ gas) of the chemical reaction diffuse away from the interfacial bonding surfaces. In some embodiments, the direct bond is strengthened using an anneal process, where the substrates are heated to and maintained at a temperature of greater than about 30° C. and less than about 450° C., for example, greater than about 50° C. and less than about 250° C., or about 150° C., for a duration of about 5 minutes or more, such as about 15 minutes. Typically, the bonds will strengthen over time even without the application of heat. Thus, in some embodiments, the method does not include heating the substrates.

In embodiments where the first and second substrates are bonded using hybrid dielectric and metal bonds, the method 70 may further include planarizing or recessing the metal features below the dielectric field surface before contacting and bonding the dielectric material layers. After the dielectric bonds are formed, the first and second substrates may be heated to a temperature of 150° C. or more and maintained at the elevated temperature for a duration of about 1 hour or more, such as between 8 and 24 hours, to form direct metallurgical bonds between the metal features.

Suitable direct dielectric and hybrid bonding technologies that may be used to perform aspects of the methods described herein include ZiBond® and DBI®, each of which are commercially available from Adeia Holding Corp., San Jose, CA, USA.

At block 74, the method 70 includes singulating at least one integrated cooling assembly 203 from the bonded first and second substrates. Singulation after bonding may impart distinctive structural characteristics on the integrated cooling assembly 203 as the cold plate 206 has the same perimeter as the semiconductor device 204 bonded thereto. Thus, the sidewalls (e.g., side surfaces) of the cold plate 206 are typically flush with the sidewalls (e.g., side surfaces) of the semiconductor device 204 about their common perimeters. In some embodiments, the cold plate 206 is singulated from the first substrate using a process that cuts or divides the first substrate in a vertical plane, i.e., in the Z-direction. In those embodiments, the side surfaces of the cold plate 206 are substantially perpendicular to the backside 220 of the semiconductor device 204, i.e., a horizontal (X-Y) plane of an attachment interface between the semiconductor device 204 and the cold plate 206. In some embodiments, the cold plate 206 is singulated using a saw or laser dicing process.

At block 76, the method 70 may include connecting the integrated cooling assembly 203 to the package substrate 202 and sealing a package cover 208 comprising inlet and outlet openings 212 to the integrated cooling assembly 203 by use of a sealing material layer 222, such as a molding compound that is cured.

At block 78, the method 70 may include, before or after sealing the package cover 208 to the integrated cooling assembly 203, forming inlet and outlet openings 222A in the sealing material layer 222 to fluidly connect the inlet and outlet openings 212 of the package cover 208 to the cold plate 206.

FIG. 8 shows an example method of attaching a silicon preform to an MCM, in accordance with embodiments of the present disclosure. The example method shows a top view of the MCM 800, silicon preform 820, and MCM assembly 830 (e.g., silicon preform 820 attached to the MCM 800 with mold compound 812). Although a particular number of chips and a particular arrangement of chips are shown and described in various figures and embodiments of MCMs in the present disclosure, any suitable number and any suitable arrangement of chips may be used to form the MCMs. Although a particular design of silicon preform is shown in various figures and embodiments of the present disclosure, any suitable design of silicon preform (e.g., any suitable number, any suitable arrangement of silicon preforms) may be used.

At block 80, a method may include providing an MCM 800. The MCM 800 comprises chips 801-807 disposed in or surrounded by a mold compound 812 (e.g., mold, molding material) disposed on a substrate 810. In some embodiments, chip 801 may be a processor and chips 802, 803, 804, 805, 806, 807 may be HBMs. In some embodiments, providing the MCM 800 may comprise assembling the chips 801-807 in the mold compound 812 on the substrate 810 to form the MCM 800.

At block 82, the method may include providing a silicon preform 820. The silicon preform 820 may be designed to fit around chips 801-807 of an MCM 800. The silicon preform 820 may be a single piece of silicon. The silicon preform 820 may be laser cut or dry etched from a silicon wafer. The shape and size of the silicon preform 820 may accommodate the mold compound 812 surrounding the chips 801-807 of the MCM 800. In some embodiments, providing a silicon preform 820 may comprise laser cutting or dry etching a silicon wafer to form the silicon preform 820.

At block 84, the method may include attaching the silicon preform 820 to the MCM 800 to form an MCM assembly 830. An MCM assembly 830 may be formed by attaching the silicon preform 820 to the MCM 800. The silicon preform 820 may be attached to the MCM 800 using mold compound 812. The mold compound 812 may add support at edges of the MCM and help protect passive components (e.g., capacitors 229 in FIG. 3, capacitors 1010 as shown in FIGS. 10A, 11A, etc.) from a polishing process. The mold compound 812 or mold material may comprise silica or a large amount of silica, making it more compatible with grinding and polishing processes. In some embodiments, the silicon preform 820 may be attached to the MCM 800 using adhesive (e.g., epoxy, any suitable adhesive, etc.) or underfill.

MCM chip assemblies may have substantial curvature on the order of 80-100 microns over a distance of about 50 mm (e.g., 50 mm, 45-55 mm, etc.). This amount of curvature makes it challenging or impractical for bonding to a cold plate or sealing a liquid manifold to the cold plate. MCM modules typically have solder balls applied to the bottom of the substrate, which make it unsuitable for holding the module with any sort of vacuum chuck.

FIGS. 9A-9D shows a top view of example silicon preform designs for a panel of MCMs, in accordance with embodiments of the present disclosure. In FIG. 9A, each MCM has a corresponding silicon preform. In FIG. 9B, the MCMs have one silicon preform. In FIGS. 9C and 9D, the silicon preform design includes strips of silicon preform. Although silicon preforms may have a particular shape in the embodiments of the various figures of the present disclosure, a silicon preform may have any suitable shape (e.g., frame shape, or pieces of a frame to border an MCM). Although a specific number of silicon preforms shown in FIGS. 9A-9D, any suitable number and arrangement of silicon preforms may be used. In FIGS. 9A-9D, the panel may be an organic substrate or a non-silicon substrate. In some embodiments, the plurality of MCMs may be on a wafer or an interposer wafer (e.g., silicon wafer), and groups of plurality of chips may be assembled as MCMs on a wafer. A wafer may be a round or circular type shape instead of the rectangular substrates in FIGS. 9A-9D. An interposer wafer may provide interconnections of the parts and may be attached to another substrate (e.g., a substrate with non-silicon material, organic substrate). The chips or groups of MCMs may be applied and processed in a panel or wafer form before singulation (e.g., polishing process, or processes as shown in FIGS. 10A-10C, 11A-11F applied to panel or wafer form).

FIG. 9A shows a panel assembly 900 comprising multiple groups of chips (e.g., MCMs) disposed in or surrounded by mold compound 812 on a substrate 910 with multiple silicon preforms 820 attached via mold compound 812 to surround each group of chips. Substrate 910 may be a panel or a wafer. In some embodiments, a wafer may be an interposer wafer. Although an array of six groups of chips (e.g., MCMs) is shown with an arrangement of two rows and three groups of chips in each row, there may be any suitable arrangement and number of groups of chips in a panel. In some embodiments, the panel assembly 900 may be a processed panel assembly, wafer assembly, or processed wafer assembly.

FIG. 9B shows a panel assembly 920 comprising multiple groups of chips (e.g., MCMs) disposed in or surrounded by a mold compound 812 on a substrate 924 with a one-piece silicon preform 922. Substrate 924 may be a panel or a wafer. In some embodiments, a wafer may be an interposer wafer. Although an array of four groups of chips (e.g., MCMs) is shown with an arrangement of two rows and two groups of chips in each row, there may be any suitable arrangement and number of groups of chips in a panel. In some embodiments, the panel assembly 920 may be a processed panel assembly, wafer assembly, or processed wafer assembly.

FIG. 9C shows a panel assembly 930 comprising multiple groups of chips (e.g., MCMs) disposed in or surrounded by a mold compound 812 on a substrate 934 with a silicon preform design in which strips of silicon preform 932 are used. The strips of silicon preform 932 may be rectangularly-shaped silicon preforms 932 adjacent to multiple groups of chips or MCMs (e.g., chips 802-804 of multiple groups of chips, chips 805-807 of multiple groups of chips). The silicon preform design may also include a cross-shaped silicon preform 932 adjacent to chips 802, 801, 805 and/or chips 804, 801, and 807. Substrate 934 may be a panel or a wafer. In some embodiments, a wafer may be an interposer wafer. Although an array of four groups of chips (e.g., MCMs) is shown with an arrangement of two rows and two groups of chips in each row, there may be any suitable arrangement and number of groups of chips in a panel. In some embodiments, the panel assembly 930 may be a processed panel assembly, wafer assembly, or processed wafer assembly.

FIG. 9D shows another silicon preform design in which strips of silicon preform are used. FIG. 9D shows a panel assembly 930 comprising multiple groups of chips (e.g., MCMs) disposed in or surrounded by a mold compound 812 on a substrate 944 with a silicon preform design in which strips of silicon preform 942 are used. The strips of silicon preform 942 may be adjacent to chips 802, 805, chips 804 and 807, and other pieces of silicon preform 942. The other pieces of silicon preform 942 may include rectangularly-shaped silicon preform 942 along sides of chips 802-804 or along a side of chip 801. Substrate 944 may be a panel or a wafer. In some embodiments, a wafer may be an interposer wafer. Although an array of four groups of chips (e.g., MCMs) is shown with an arrangement of two rows and two groups of chips in each row, there may be any suitable arrangement and number of groups of chips in a panel. In some embodiments, the panel assembly 940 may be a processed panel assembly, wafer assembly, or processed wafer assembly.

FIGS. 10A-10C show a method of forming a cooling assembly with an MCM using a silicon preform, in accordance with embodiments of the present disclosure. FIG. 10A shows a cross-sectional view of a planarization process. FIGS. 10B-10C show preparing surfaces for bonding and bonding a cold plate to form the cooling assembly. The method is illustrated using cross sectional side views corresponding to (e.g., similar to or the same as) the MCM 800 and silicon preform 820 forming the MCM assembly 830 of FIG. 8 (e.g., cross sectional view through chips 803, 801, and 806).

At block 1001, the method includes providing an MCM assembly. Providing the MCM assembly may include attaching the silicon preform 820 to the MCM. The cross section shows MCM chips 801, 803, and 806 disposed in or surrounded by a mold compound 812 disposed on the substrate 1012. The MCM comprises capacitors 1010 disposed on the substrate 1012. The capacitors 1010 may be disposed on a first side (e.g., top surface) of substrate 1012, and solder balls 1014 may be disposed on a second side (e.g., bottom surface) of the substrate 1012. The mold compound 812 (e.g., mold, molding material) covers the capacitors 1010 and the silicon preform 820 is attached to the mold compound 812. The silicon preform 820 may be attached to substrate 1012 using the mold compound 812. In some embodiments, the silicon preform 820 may be attached to substrate 1012 using other adhesive (e.g., any suitable adhesive). In some embodiments, capacitors 1010 may be any suitable component (e.g., passive element, resistor, any suitable component such as those mentioned throughout the present disclosure), and the solder balls 1014 may be any suitable conductive feature (e.g., conductive bump, etc.).

At block 1002, the method includes attaching a plate 1018 to the bottom of the MCM with wax 1016 or any suitable removable material. The wax 1016 may be solvent soluble wax. In some embodiments, the plate 1018 may be referred to as a protective plate. The plate 1018 may be a metal plate, silicon plate, or a carrier wafer.

At block 1003, the method includes back grinding or backgrinding the silicon preform 820, the MCM chips 801, 803, 806, and the mold compound 812 to planarize a surface of the MCM assembly. The method may further include polishing (e.g., CMP) the silicon preform 820, MCM chips 801, 803, and 806 (e.g., silicon surfaces) with a hard pad such as IC1000 polishing pad to remove grind damage.

At block 1004, the method includes removing a portion of the mold compound 812. The method may include etching (e.g., wet or dry etching) to remove a portion of the mold compound 812. In some embodiments, a height of the mold compound 812 may be lowered by 0.5 microns to 2 microns in height. The method may further include polishing (e.g., CMP) the silicon preform 820, MCM chips 801, 803, and 806 (e.g., silicon surfaces) using a soft pad (e.g., soft Polytex type pad) to reduce the surface roughness. In some embodiments, the polishing using a soft pad may be referred to as a touch polish, to clean off residue and smooth a surface. In some embodiments, the soft pad is a softer pad (e.g., softer than a hard pad used at block 1003 or any suitable hard pad). The method may include polishing the silicon preform 820, MCM chips 801, 803, and 806 (e.g., silicon surfaces) to a surface roughness, Ra, of 1.5 to 2.5 angstroms. In some embodiments, the surface roughness may be reduced to less than 5, 4, 3, 2.5, or 2 angstroms.

At block 1005, the method includes forming a dielectric layer 1019 (e.g., native oxide) on the silicon preform 820, MCM chips 801, 803, and 806 (e.g., silicon surfaces). A bondable native oxide may be formed using 5 to 10% H₂O₂ in DI water heated to between 40° C. and 60° C. In some embodiments, the dielectric layer 1019 may be formed using any suitable technique at any suitable temperature. In some embodiments, the surfaces of the chips and silicon preform (e.g., dielectric layer 1019) may be prepared for direct bonding using any suitable techniques, such as those described in the present disclosure. In some embodiments, a dielectric layer 1019 or an inorganic material may be coated or deposited on the silicon preform 820, MCM chips 801, 803, and 806, and the molding material 812. In some embodiments, the coating or deposition may take place before or after the planarization process or processes. In some embodiments, multiple dielectric layer or inorganic coating and planarization steps may be used to form a planar and smooth bonding surface on the backside of the chips and the silicon preform.

At block 1006, the method includes attaching a cold plate to the MCM assembly. The method may include bonding (e.g., directly bonding) the cold plate 1026 to the MCM assembly. The cold plate 1026 comprises a first portion 1020 (e.g., first part, top part) of the cold plate attached to (e.g., bonded to) a second portion 1022 (e.g., second part, bottom part, cover plate) of the cold plate. In some embodiments, the cold plate 1026 may be any suitable cold plate (e.g., silicon cold plate, a single piece cold plate, any of the cold plates described throughout the present disclosure, etc.). In some embodiments, the cold plate 1026 is similar to the cold plate 206 (e.g., as shown in FIG. 4). The second portion 1022 of the cold plate 1026 has a dielectric layer 1023 (e.g., an oxide layer) for bonding. The oxide layer may be 0.1 to 1 micron thick, which is polished to an Ra value of 1.5 to 4 angstroms. In some embodiments, the oxide layer maybe polished to an Ra value of less than 5, 4, 3, 2.5, or 2 angstroms. The oxide layer may be activated for bonding using a nitrogen plasma (e.g., as described above in the present disclosure). In some embodiments, the dielectric layer 1023 may be prepared for direct bonding using any suitable techniques, such as those described in the present disclosure. The method may include applying heat to or heating the structure to from 50° C. to 80° C. for enhancing the bond strength.

At block 1007, the method includes removing the plate 1018. The method may include heating the plate 1018 to allow the wax 1016 to soften to remove the plate 1018. After removing the plate 1018, the method may include cleaning off the wax 1016 using a solvent (e.g., any suitable solvent). The method may include annealing the structure at 150° C. for 15 minutes to increase or maximize the bond strength or bond energy.

FIGS. 11A-11E shows another method of forming a cooling assembly with an MCM and a silicon preform, in accordance with embodiments of the present disclosure. FIG. 11A shows a cross-sectional view of a planarization process. FIGS. 11B-11C show preparing surfaces for bonding and bonding a cold plate to form the cooling assembly. The method is illustrated using cross sectional side views corresponding to (e.g., similar to or the same as) the MCM 800 and silicon preform 820 forming the MCM assembly 830 of FIG. 8 (e.g., cross sectional view through chips 803, 801, and 806), except the MCM assembly of FIGS. 11A-11E further includes a first metal stiffener. FIGS. 11D-11E show attaching a manifold to the cold plate using a second metal stiffener for alignment.

At block 1101, the method includes providing an MCM assembly. Providing the MCM assembly may include attaching the silicon preform 820 to the MCM. The cross section shows MCM chips 801, 803, and 806 disposed in or surrounded by a mold compound 812 disposed on the substrate 1112. The MCM comprises capacitors 1010 disposed on the substrate 1112. The capacitors 1010 may be disposed on a first side (e.g., top surface) of substrate 1112, and solder balls 1014 may be disposed on a second side (e.g., bottom surface) of the substrate 1112. A metal stiffener 1120 may be disposed on the first side (e.g., top surface) of substrate 1112 at the edges of the substrate. In some embodiments, the metal stiffener 1120 may be disposed on an outside portion of a group of MCM chips. The metal stiffener 1120 may be attached to the substrate 1112 using any suitable technique (e.g., bonding, soldering, adhesive, etc.) A metal stiffener 1120 may be a structural element included in the MCM assembly for reinforcement (e.g., maintain shape of the MCM). The metal stiffener 1120 may be formed using a metal material such as aluminum, or any suitable material. The silicon preform 820 may be designed to fit around the mold surrounding the chips of the MCM and inside a boundary of the metal stiffener 1120. The mold compound 812 (e.g., mold, molding material) covers the capacitors 1010 and the silicon preform 820 is attached to the mold compound 812. The silicon preform 820 may be attached to substrate 1112 using the mold compound 812.

At block 1102, the method includes attaching a plate 1118 to the bottom of the MCM with wax 1016 or any suitable removable material. The wax 1016 may be solvent soluble wax. The plate 1118 may be a protective plate, a metal plate, a silicon plate, or a carrier wafer. In some embodiments, block 1102 is similar to block 1002 of FIG. 10A.

At block 1103, the method includes recessing the metal stiffener 1120 below a final height of the chips (e.g., chips 803, 801, 806, silicon preform 820, etc.). The method may include milling down the metal stiffener 1120. The metal stiffener 1120 may be recessed 20-100 microns below a height of the chips (e.g., final height of the chips, height of chips at block 1106, at block 1107, or after chips are planarized, polished, prepared for bonding). In some embodiments, the metal stiffener 1120 may be slightly below or even with surfaces of the chips 803, 801, 806 and the silicon preform 820.

At block 1104, the method includes back grinding or backgrinding the silicon preform 820, the MCM chips 801, 803, 806, and the mold compound 812 to planarize a surface of the MCM assembly. The method may further include polishing (e.g., CMP) the silicon preform 820, MCM chips 801, 803, and 806 (e.g., silicon surfaces) with a hard pad such as IC1000 polishing pad to remove grind damage. In some embodiments, block 1104 is similar to block 1003 of FIG. 10A.

At block 1105, the method includes removing a portion of the mold compound 812. The method may include etching to remove a portion of the mold compound 812. For example, a height of the mold compound 812 may be lowered by either wet etching or dry etching. In some embodiments, a height of the mold compound 812 may be lowered by 0.5 microns to 2 microns in height. The method may further include polishing (e.g., CMP) the silicon preform 820, MCM chips 801, 803, and 806 (e.g., silicon surfaces) using a soft pad (e.g., soft Polytex type pad) to reduce the surface roughness. In some embodiments, the polishing using a soft pad may be referred to as a touch polish, to clean off residue and smooth a surface. In some embodiments, the soft pad is a softer pad (e.g., softer than a hard pad used at block 1104 or any suitable hard pad). The method may include polishing the silicon preform 820, MCM chips 801, 803, and 806 (e.g., silicon surfaces) to a surface roughness, Ra, of 1.5 to 2.5 angstroms. In some embodiments, the surface roughness may be reduced to less than 5, 4, 3, 2.5, or 2 angstroms. In some embodiments, block 1105 is similar to block 1004 of FIG. 10B.

At block 1106, the method includes forming a dielectric layer 1019 (e.g., native oxide) on the silicon preform 820, MCM chips 801, 803, and 806 (e.g., silicon surfaces). A bondable native oxide may be formed using 5 to 10% H₂O₂ in DI water heated to between 40° C. and 60° C. In some embodiments, the dielectric layer 1019 may be formed using any suitable technique at any suitable temperature. In some embodiments, the surfaces of the chips and silicon preform (e.g., dielectric layer 1019) may be prepared for direct bonding using any suitable techniques, such as those described in the present disclosure. In some embodiments, block 1106 is similar to block 1005 of FIG. 10B. In some embodiments, a dielectric layer 1019 or an inorganic material may be coated or deposited on the silicon preform 820, MCM chips 801, 803, and 806, the molding material 812, and/or the metal stiffener 1120. In some embodiments, the coating or deposition may take place before or after the planarization process or processes. In some embodiments, multiple dielectric layer or inorganic coating and planarization steps may be used to form a planar and smooth bonding surface on the backside of the chips, the silicon preform, and/or the metal stiffener.

At block 1107, the method includes attaching a cold plate 1026 to the MCM assembly. In some embodiments, the cold plate 1026 is attached to the MCM assembly and the stiffener 1120. The method may include bonding (e.g., directly bonding) the cold plate to the MCM assembly. The cold plate 1026 comprises a first portion 1020 of the cold plate attached to (e.g., bonded to) a second portion 1022 of the cold plate. In some embodiments, the cold plate 1026 may be any suitable cold plate (e.g., a cold plate comprising a single piece, any of the cold plates described throughout the present disclosure, etc.) attached in any suitable orientation. In some embodiments, one or more channels of the cold plate may be across multiple chips. In some embodiments, one or more channels of the cold plate may be across a single chip. A single chip may have a single channel, multiple channels, or no channels across the chip. The second portion 1022 of the cold plate has a dielectric layer 1023 (e.g., an oxide layer) for bonding. The oxide layer may be 0.1 to 1 micron thick, which is polished to an Ra value of 1.5 to 4 angstroms. In some embodiments, the oxide layer maybe polished to an Ra value of less than 5, 4, 3, 2.5, or 2 angstroms. The oxide layer may be activated for bonding using a nitrogen plasma (e.g., as described above in the present disclosure). In some embodiments, the dielectric layer 1023 may be prepared for direct bonding using any suitable techniques, such as those described in the present disclosure. The method may include applying heat to or heating the structure to from 50° C. to 80° C. for enhancing the bond strength. In some embodiments, block 1107 is similar to block 1006 of FIG. 10C.

At block 1108, the method includes removing the plate 1018. The method may include heating the plate 1018 to allow the wax 1016 to soften to remove the plate 1018. After removing the plate 1018, the method may include cleaning off the wax 1016 using a solvent (e.g., any suitable solvent). The method may include annealing the structure at 150° C. for 15 minutes to increase or maximize the bond strength or bond energy. In some embodiments, block 1108 is similar to block 1007 of FIG. 10C.

At block 1109, the method includes attaching a second metal stiffener 1122 to the first metal stiffener 1120. The second metal stiffener 1122 may be attached via adhesive 1121. In some embodiments, mold or epoxy may be used in place of the second metal stiffener 1122. In some embodiments, the second metal stiffener 1122 may be attached via metallic bonding or dielectric or hybrid bonding.

At block 1110, the method includes attaching a manifold 1124 with adhesive such as RTV silicone rubber glue to the cold plate. The second metal stiffener (e.g., stiffener add on) may provide alignment of the manifold to the cold plate (e.g., MCM assembly). Inlets and outlets of the manifold 1124 can be sealed to the cold plate with o-rings, gaskets or adhesive or a combination thereof. A filler material 1125 may be disposed between the second metal stiffener 1122 and the cold plate 1026. The filler material 1125 may comprise any suitable material (e.g., epoxy, mold compound, etc.).

The embodiments discussed above are intended to be illustrative and not limiting. One skilled in the art would appreciate that individual aspects of the cooling assemblies, device packages, and methods discussed herein may be omitted, modified, combined, and/or rearranged without departing from the scope of the disclosure.

1. An integrated cooling assembly comprising:
a substrate;
a plurality of chips attached to the substrate;
at least one silicon preform adjacent to the plurality of chips and attached to the substrate; and
a cold plate attached to the plurality of chips and the at least one silicon preform.

2. The integrated cooling assembly of claim 1, further comprising a molding material disposed between the plurality of chips and the at least one silicon preform, wherein a surface of the molding material is recessed from a surface of the plurality of chips and the at least one silicon preform.

3. The integrated cooling assembly of claim 1, further comprising at least one capacitor disposed in a molding material between the substrate and the at least one silicon preform.

4. The integrated cooling assembly of claim 1, wherein the at least one silicon preform is a single silicon piece that surrounds the plurality of chips.

5. The integrated cooling assembly of claim 1, wherein the at least one silicon preform comprises a plurality of silicon preforms that surround the plurality of chips.

6. The integrated cooling assembly of claim 1, further comprising:
a dielectric layer on a backside of at least one chip of the plurality of chips and a dielectric layer on a backside of the at least one silicon preform; and
a dielectric layer on a side of the cold plate facing the plurality of chips and the at least one silicon preform, wherein the dielectric layer on the backside of the at least one chip and the dielectric layer on the backside of the at least one silicon preform is directly bonded to the dielectric layer on the side of the cold plate facing the plurality of chips and the at least one silicon preform.

7. The integrated cooling assembly of claim 1, wherein the cold plate comprises a first portion and a second portion that are directly bonded to each other.

8. The integrated cooling assembly of claim 1, further comprising a metal stiffener attached to the substrate and surrounding the at least one silicon preform.

9. The integrated cooling assembly of claim 8, further comprising a molding material disposed between the plurality of chips and the at least one silicon preform, wherein a surface of the molding material is recessed from a surface of the plurality of chips, the at least one silicon preform, and the metal stiffener.

10. The integrated cooling assembly of claim 8, wherein the metal stiffener is a first metal stiffener; and
the integrated cooling assembly further comprises:
a second metal stiffener attached to the first metal stiffener via adhesive; and
a manifold attached to the cold plate and adjacent to the second metal stiffener.

11. A method comprising:
attaching a silicon preform to a substrate comprising a plurality of chips disposed in a molding material, wherein the silicon preform surrounds the plurality of chips;
backgrinding the chips, the silicon preform, and the molding material to form a planar surface;
polishing the chips and the silicon preform using a hard pad;
recessing the molding material below a surface of the chips and the at least one silicon preform;
polishing the chips and the silicon preform using a soft pad; and
bonding a cold plate to the plurality of chips and the silicon preform.

12. The method of claim 11, further comprising:
forming a dielectric layer on a backside of at least one chip of the plurality of chips;
forming a dielectric layer on a backside of the silicon preform;
forming a dielectric layer on a side of the cold plate; and
bonding the dielectric layer on the backside of the at least one chip and the dielectric layer on the backside of the silicon preform to the dielectric layer on the side of the cold plate.

13. The method of claim 11, further comprising:
forming the cold plate by directly bonding a first portion of the cold plate to a second portion of the cold plate.

14. The method of claim 11, further comprising, prior to backgrinding the chips, the silicon preform, and the molding material to form the planar surface, recessing a metal stiffener surrounding the silicon preform to be below the height of the chips.

15. The method of claim 14, wherein the metal stiffener is a first metal stiffener; and
the method further comprises:
attaching a second metal stiffener to the first metal stiffener via adhesive; and
attaching a manifold to the cold plate adjacent to the second metal stiffener.

16. The method of claim 11, further comprising:
prior to backgrinding the chips, the silicon preform, and the molding material to form the planar surface, attaching a plate to a bottom of the substrate; and
subsequent to bonding the cold plate to the plurality of chips and the silicon preform, removing the plate.

17. A method comprising:
attaching at least one silicon preform to a substrate comprising groups of plurality of chips disposed in a molding material, wherein the at least one silicon preform is disposed in an area adjacent to at least one group of the plurality of chips;
backgrinding the groups of the plurality of chips, the at least one silicon preform, and the molding material to form a planar surface;
polishing the chips and the at least one silicon preform using a hard pad;
recessing the molding material below a surface of the chips and the at least one silicon preform;
polishing the chips and the at least one silicon preform using a soft pad; and
bonding at least one cold plate to the at least one silicon preform and the respective group of the plurality of chips.

18. The method of claim 17, wherein:
the at least one silicon preform is a plurality of silicon preforms; and
the at least one cold plate is a plurality of cold plates.

19. The method of claim 17, wherein the at least one silicon preform is a single silicon preform.

20. The method of claim 17, wherein the at least one silicon preform is a rectangular shaped strip that is adjacent to more than one group of the plurality of chips.
